(19) United States
(12) Patent Application Publication
(10) Pub. No.: US 2023/0411191 A1
(43) Pub. Date: Dec. 21, 2023

(54) PURGING GAS AMPLIFIER

(71) Applicant: ENTEGRIS, INC., Billerica, MA (US)

(72) Inventors: Matthew A. Fuller, Colorado Springs, CO (US); Aleksandr A. Yakuba, Colorado Springs, CO (US); Mark V. Smith, Colorado Springs, CO (US)

(21) Appl. No.: 18/211,158

(22) Filed: Jun. 16, 2023

Related U.S. Application Data
(60) Provisional application No. 63/353,416, filed on Jun. 17, 2022.

(51) Int. Cl. H01L 21/673

(52) U.S. Cl. CPC H01L 21/67389

(57) ABSTRACT

A container includes a deflector, disposed in an interior of a substrate container, having a longitudinal opening and a deflection surface and a gas distributor configured to provide a purging gas to purge an interior of a substrate container. The gas distributor is configured such that at least a portion of the purging gas flows into a gap formed between the gas distributor and the deflector. The deflector is configured such that at least a portion of the purging gas in the gap flows through the longitudinal opening. The deflector directs a gas flow pattern of the purging gas from the gas distributor to an outlet of the substrate container to improve purging efficacy of the substrate container.

### FIELD

This disclosure is directed to one or more embodiments of a substrate container with one or more deflectors disposed therein to improve a gas flow pattern within the substrate container and improve purging efficacy.

### BACKGROUND

Wafer containers are used during the storage and/or etching of semiconductor wafers. When wafers are stored in a wafer container, undesirable gases, e.g., moisture, may seep in. An undesirable gas can be purged from a container by the introduction of a purging gas into the wafer container by one or more gas distributors.

### SUMMARY

This disclosure is directed to one or more embodiments of a substrate container with one or more deflectors disposed therein to improve a gas flow pattern within the substrate container and improve purging efficacy.

In some embodiments, a system includes a deflector, disposed in an interior of a substrate container, having a longitudinal opening and a deflection surface; and a gas distributor configured to provide a purging gas to purge the interior of the substrate container. The gas distributor is configured such that at least a portion of the purging gas flows into a gap formed between the gas distributor and the deflector. The deflector is configured such that at least a portion of the purging gas in the gap flows through the longitudinal opening. The deflector is configured to direct a gas flow pattern of the purging gas from the gas distributor to an outlet of the substrate container to improve purging efficacy of the substrate container. In an embodiment, the deflector includes a first piece and a second piece, wherein the first piece and the second piece are configured to be joined to one another. In an embodiment, the first piece is configured to engage with the gas distributor. In an embodiment, the first piece is configured to engage with a feature provided on the substrate container.

In some embodiments, a system includes a substrate container having an interior disposed to store substrates; a deflector, disposed in the interior of the substrate container, having a longitudinal opening; and a gas distributor disposed to provide a purging gas to purge the interior of the substrate container. The gas distributor is configured such that at least a portion of the purging gas flows through the longitudinal opening into the interior of the substrate container. The longitudinal opening is disposed to direct the purging gas toward a central volume of the interior of the substrate container. The deflector can direct the gas flow pattern of the purging gas from the gas distributor to an outlet of the substrate container, to improve purging efficacy of the substrate container. In an embodiment, the deflector includes a first piece and a second piece, wherein the first piece and the second piece are configured to be joined to one another. In an embodiment, the first piece is configured to engage with the gas distributor. In an embodiment, the first piece is configured to engage with a feature provided on the substrate container.

In some embodiments, the longitudinal opening is disposed to direct the purging gas away from the central volume, toward a front opening of the substrate container, or toward a back of the substrate container.

### BRIEF DESCRIPTION OF THE DRAWINGS

References are made to the accompanying drawings that form a part of this disclosure and which illustrate the non-limiting example embodiments of a purging gas amplifier. The use of the same reference numbers in different figures indicates similar or identical items.

FIG. 1 shows a substrate container, according to one or more example embodiments of a purging gas amplifier.

FIG. 2A shows a cross-sectional view of the substrate container, according to the example embodiment of FIG. 1.

FIG. 2B shows a perspective view of a deflector, according to the example embodiment of FIG. 1.

FIG. 3 shows a perspective view of a gas distributor and a deflector, according to one or more example embodiments of a purging gas amplifier, according to one or more example embodiments of a purging gas amplifier.

FIG. 4 shows a cross-sectional view of the gas distributor and the deflector, according to the example embodiment of FIG. 3.

FIG. 5 shows a gas distributor and a deflector, according to one or more example embodiments of a purging gas amplifier.

FIG. 6 shows a gas distributor and a deflector, according to one or more example embodiments of a purging gas amplifier.

FIG. 7 is a cross-sectional view of a substrate container, according to one or more example embodiments of a purging gas amplifier.

FIG. 8A is partial a cross-sectional view of a substrate container, according to one or more example embodiments of a purging gas amplifier.

FIG. 8B is another partial a cross-sectional view of a substrate container, according to one or more example embodiments of a purging gas amplifier.

FIG. 8C is yet another partial a cross-sectional view of a substrate container, according to one or more example embodiments of a purging gas amplifier.

FIG. 9 shows a perspective view of a gas distributor and a deflector, according to one or more example embodiments of a purging gas amplifier.

FIG. 10 shows a schematic view of a mating surface on the substrate container, according to the example embodiment of FIG. 9.

FIG. 11 shows an indexer, according to one or more example embodiments of a purging gas amplifier.

FIG. 12A shows a perspective view of a gas distributor and a deflector, according to one or more example embodiments of a purging gas amplifier.

FIG. 12B shows a cross-sectional view of the gas distributor and the deflector, according to the example embodiment of FIG. 12A.

FIG. 12C shows a cross-sectional view of the gas distributor and the deflector, according to the example embodiment of FIG. 12A.

FIG. 12D shows a cross-sectional view of the gas distributor and the deflector, according to the example embodiment of FIG. 12A.

FIG. 13 shows a cross-sectional view of the substrate container, according to one or more example embodiments of a purging gas amplifier.

FIG. 14 shows a cross-sectional view of a deflector disposed in a substrate container, according to one or more example embodiments of a purging gas amplifier.

FIG. 15A is a table summarizing experimental results of gas distributors and deflectors that improve purging efficacy, according to one or more example embodiments of a purging gas amplifier.

FIG. 15B is a table summarizing experimental results of gas distributors and deflectors that improve purging efficacy, according to one or more example embodiments of a purging gas amplifier.

FIG. 16 shows a test method of a substrate container having one or more gas distributors and deflectors disposed therein, according to one or more example embodiments of a purging gas amplifier.

FIG. 17 shows test results of a substrate container having one or more gas distributors and deflectors disposed therein, according to one or more example embodiments of a purging gas amplifier.

FIG. 18 shows test results of a substrate container having one or more gas distributors and deflectors disposed therein, according to one or more example embodiments of a purging gas amplifier.

FIG. 19 shows a cross-sectional view of a deflector disposed in a substrate container, according to one or more example embodiments of a purging gas amplifier.

FIG. 20 shows a cross-sectional view of a diffuser and a deflector according to an embodiment.

FIG. 21A shows an exploded perspective view of a deflector according to an embodiment.

FIG. 21B shows another exploded perspective view of the deflector of FIG. 21A.

FIG. 22 shows a flowchart of a method for installing a deflector into a substrate container.

### DETAILED DESCRIPTION

This disclosure is directed to a substrate container with one or more deflectors disposed therein to improve a gas flow pattern within the substrate container and improve purging efficacy.

By including one or more deflectors in a substrate container, a gas flow pattern of the purging gas can be improved during purging and thus improve the purging efficacy of the substrate container. The deflectors can, for example, direct the gas flow pattern of the purging gas more toward the substrates disposed within the substrate container such that a larger portion of the purging gas flow near or between the substrates and a smaller portion flows around the substrates. The portion flowing near or between the substrates can more effectively remove unwanted vapor or particles from the substrates, and thus improve the performance and purging efficacy of the substrate containers. In some embodiments, a deflector can be a purging gas amplifier.

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not intended to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Particular embodiments of the present disclosure are described herein with reference to the accompanying drawings; however, it is to be understood that the disclosed embodiments are merely examples of the disclosure, which may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure. In this description, as well as in the drawings, like-referenced numbers represent elements that may perform the same, similar, or equivalent functions.

The scope of the disclosure should be determined by the appended claims and their legal equivalents, rather than by the examples given herein. For example, the steps recited in any method claims may be executed in any order and are not limited to the order presented in the claims. Moreover, no element is essential to the practice of the disclosure unless specifically described herein as “critical” or “essential.”

As disclosed and recited herein, “dispose” may pertain to a physical or functional feature being located, attached, engaged, coupled, etc., permanently or temporarily, relative to another physical or functional feature, via any one or means suitable of one or both of the physical or functional feature, for example, by adhesive, fitting, welding, fastener(s), friction, or the like, or a combination thereof.

As disclosed and recited herein, “stabilizer” may pertain to one or more structures that limit, reduce, or prevent movement of a gas distributor and/or a deflector relative to one another or relative to a substrate container including said gas distributor and/or deflector. As used herein, said stabilizer can be connected to any one or more of the gas distributor, deflector, and/or the substrate container. By including a stabilizer 145 reducing or limiting the movements, the relative position can be unchanged to maintain the flow pattern that optimizes the purging efficacy. By including a stabilizer reducing or limiting such movement, the relative position can be maintained, so as to to maintain a flow pattern providing high purging efficacy.

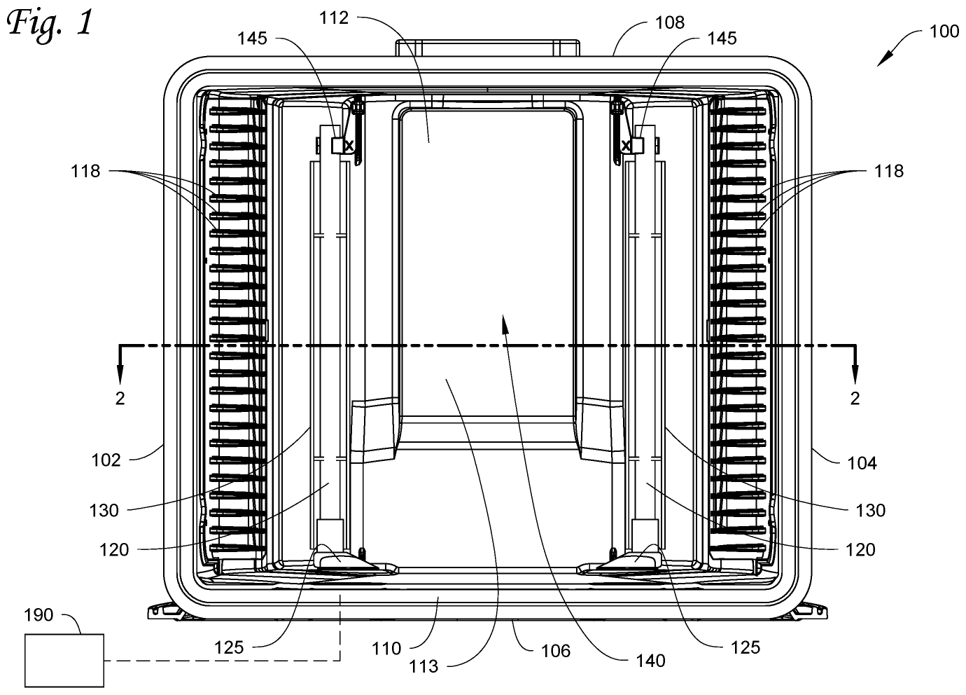

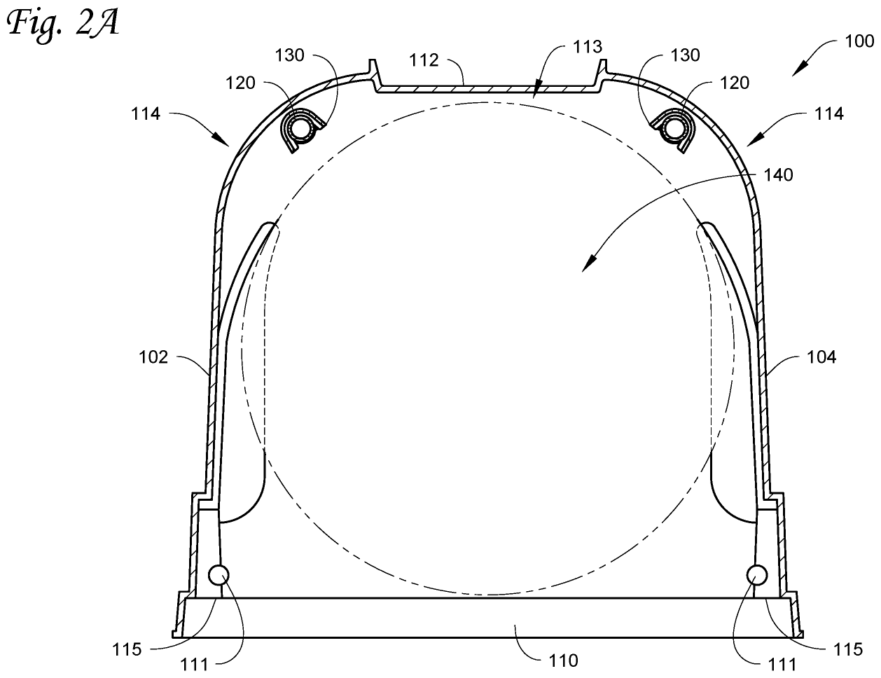

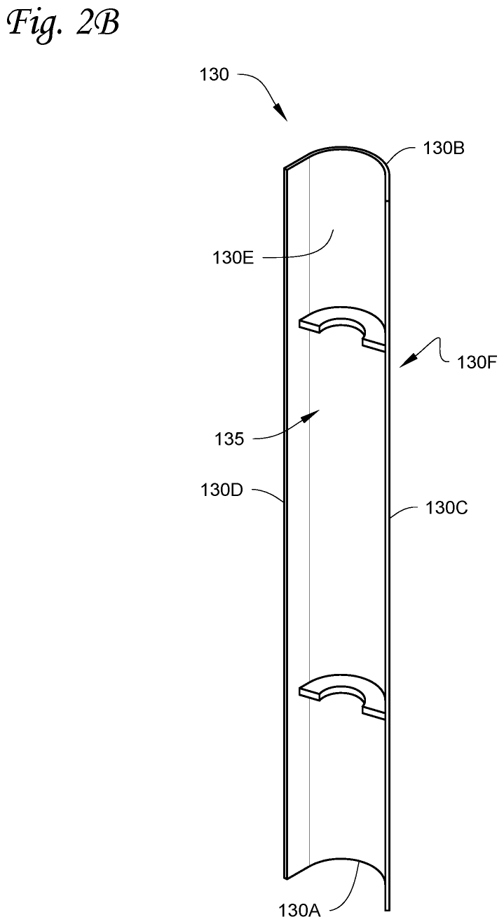

FIG. 1 shows a substrate container 100, according to one or more example embodiments of a purging gas amplifier. FIG. 2A shows a cross-sectional view of the substrate container 100, according to the example embodiment of FIG. 1. The cross-sectional view shown in FIG. 2A can be taken along line 2-2 in FIG. 1.

As shown in FIGS. 1 and 2, the substrate container 100 includes a first lateral side 102, a second lateral side 104, a bottom side 106, a top side 108, a back 112, and a front opening 110.

The first lateral side 102, the second lateral side 104, the bottom side 106, and the top side 108 define the front opening 110 of the substrate container 100. The front opening 110 can be closed by a door coupled to the substrate container 100. The substrate container 100 can be accessed by moving (e.g., opening, removing) the door. For example, the door may be coupled to the substrate container 100 by fitting the door into the front opening 110 of the substrate container 100 and optionally operating a latch (not shown). The door can be operated (e.g., opened or closed) manually or automatically. The door can be operated by an operator, a robotic arm, or the like. The door can include one or more latch to engage with the substrate container 100. When closed, the door is configured to seal the substrate container 100 from the ambient around the substrate container against foreign matters such as, but not limited to, moisture, dust particles, or the like. The back 112 is disposed at a back end 113 (shown by FIGS. 1 and 2) of the substrate container 200. The first lateral side 102, the second lateral side 104, the bottom side 106, the top side 108, the back 112, and door of the substrate container 100 divide an interior 140 of the substrate container 100 from an exterior of the substrate container 100.

The interior 140 is disposed in the substrate container 100 and defined by the first lateral side 102, the second lateral side 104, the bottom side 106, the top side 108, the back 112, and the front opening 110. The interior 140 can be a space that is utilized to store one or more substrates. The interior 140 can contain other components of the substrate container 100, such as the gas distributors 120, the deflectors 130, or the like.

The first lateral side 102 and the second lateral side 104 can each include one or more shelves 118 that protrude laterally from the respective lateral sides into the interior 140. The respective shelves 118 from the first lateral side 102 and the second lateral side 104 cooperatively define substrate slots that are each configured to accommodate and support a substrate. When the substrates are held in respective substrate slots in the substrate container 100, a volume occupied by the substrates can be an interior volume 101. In some embodiments, the interior volume 101 can be a cylindrical volume that is concentric with the substrates held in the substrate container 100, and be bounded by the top side 108 and the bottom side 106 of the substrate container 100.

In some embodiments, the substrates can be, for example, one or more substrates used for semiconductor manufacturing. In some embodiments, the substrate container 100 is a container to accommodate one or more substrates. In some embodiments, the substrate container 100 can be, for example, a front-opening unified pod (FOUP).

In some embodiments, one or more purging gas inlets 125 can be disposed on the substrate container 100. The purging gas inlets 125 are interfaced to a purging gas source 190. The purging gas source 190 can interface with the purging gas inlets 125 by fluidly connecting the purging gas source 190 and the purging gas inlet 125 and supplies the purging gas that is used to purge the interior 140 of the substrate container 100.

It is appreciated that locations of the purging gas inlets 125 are illustrative and are not limited to the illustrated locations of the substrate container 100. For example, at least a portion of the purging gas inlets 125 can be disposed in a shoulder volume 114 of the substrate container 100 and/or a lip volume 115 of the substrate container 100. It is further appreciated that one or more purging gas inlets 125 can be disposed on any one or more of the first lateral side 102, the second lateral side 104, the bottom side 106, and the top side 108 of the substrate container 100.

In the illustrative example of FIG. 1, the purging gas source 190 is shown to be fluidly connected or interfaced to the substrate container 100 at the bottom side 106. It is appreciated that the purging gas source 190 can be fluidly connected to the substrate container 100 from any of the first lateral side 102, the second lateral side 104, the bottom side 106, the top side 108, and the back 112.

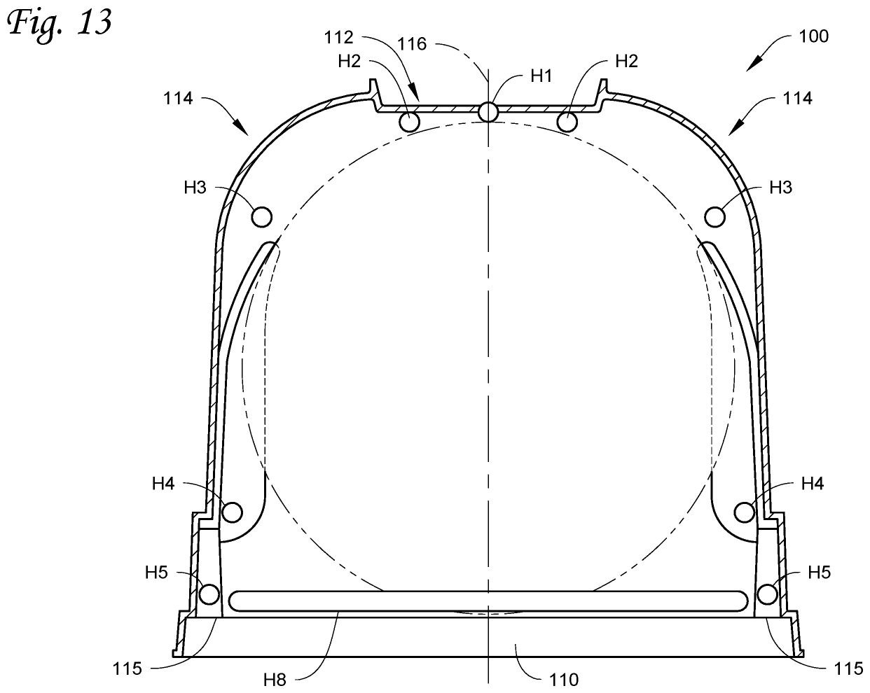

The shoulder volume 114 can be disposed in or near the back end 113 of the interior 140 of the substrate container 100. In some embodiments, the shoulder volume 114 is a volume in a rear end of the interior 140 of the substrate container 100 between the interior volume 101, the bottom side 106, the top side 108, and the back 112. For example, the shoulder volume 114 can include the location H3 (as shown in FIG. 13 and described below). The location H3 is disposed at or near the back end 113 and disposed closed to the substrates such that the purging gas is directed by the deflector 130 at a location closer to the substrates. Being closer the substrate, the deflector 130 can create a stronger directive effect in directing the gas flow pattern in the substrate container to flow between and around the substrates, purging away any foreign matters. The foreign matters can include any solid, liquid, or vapor substance that interfere with the substrates. Example of foreign matters can include, but not limited to, moisture, dust particles, or the like. The rear end of the interior 140 of the substrate container 100 can be an end of the interior 140 opposite to the door of the substrate container 100 relative to a center of the substrate container 100.

The lip volume 115 can be disposed in or near the front opening 110 of the interior 140 the substrate container 100. In some embodiments, the lip volume 115 is a volume in a front end of the interior 140 of the substrate container 100 between the interior volume 101, the bottom side 106, the top side 108, and the front opening 110. The frond end of the interior 140 of the substrate container 100. The interior 140 can be an end of the interior 140 adjacent to the door of the substrate container 100.

One or more gas distributors 120 can be disposed in the substrate container 100 to distribute the purging gas from the purging gas source 190. For example, the gas distributor 120 can guide the purging gas to flow longitudinally, relative to the gas distributor 120, before disbursing laterally into the interior 140 of the substrate container 100. In some embodiments, one or more of the gas distributors 120 are disposed on the purging gas inlets 125 to distribute the purging gas into the interior 140 of the substrate container 100. In some embodiments, the purging gas can flow laterally in any direction, including away from a center of the substrate container 100.

One or more deflectors 130 can be disposed on any one or more of the gas distributors 120 to direct the purging gas flowing from a respective one of the gas distributors 120. For example, the deflector 130 can direct the purging gas by changing an angle of one or more of the surfaces of the deflector 130 onto which the purging gas is directed. Accordingly, in some embodiments, the deflector directs the purging gas inward (i.e., toward the interior volume 101 and/or away from the first lateral side 102 and the second lateral side 104). In other embodiments, the deflector directs the purging gas outward (i.e., away from toward the interior volume 101 and/or toward the first lateral side 102 and the second lateral side 104).

FIG. 2B shows a perspective view of the deflector 130, according to the example embodiment of FIG. 1. The deflector 130 can include one or more structures, in various shapes, that deflect purging gas in the substrate container 100. For example, the deflector 130 can be an elongated member having a first end 130A and a second end 130B, a first side 130C, a second side 130D, a first surface 130E, and a second surface 130F. The first surface 130E and/or the second surface 130F can be curved such that the first side 130C and the second side 130D are disposed, relative to each other, to form a longitudinal opening 135. In some embodiments, a distance between the first side 130C and the second side 130D can be selected according to a diameter of the distributor 120. For example, in some embodiments, the distance can be 0.75 to mm.

The deflector 130 can be made from any material(s) (e.g., plastic, metal, or the like, or a combination thereof) suitable to deflect purging gas in the substrate container 100. In some embodiments, the material can be selected to withstand operating and/or cleaning processes of the substrate container 100, such as the operating and/or cleaning temperature, pressure, chemicals, or the like.

Returning to FIG. 2A, the deflector 130 is disposed to direct a gas flow pattern of the purging gas in the substrate container 100 based on a disposition of one or more of interior surfaces of the deflector 130. For example, in some embodiments, the deflector 130 modifies the gas flow pattern provided by the interior surfaces by directing the purging gas further toward a central volume or the interior volume 101 and/or away from the first lateral side 102 and the second lateral side 104. For example, without a deflector 130, when the purging gas is exiting the gas distributor 120, the purging gas can disperse in all directions away from the gas distributor 120. Having a deflection surface 136 disposed over the gas distributor 120 blocking some flow directions toward the lateral side 102 or 104, a deflector 130 can change the flow direction of at least a portion of the purging gas toward the substrates such that foreign matters on or near the substrate is purged away by the purging gas. In some embodiments, the deflector 130, by directing purging gas more toward the center of a substrate container 100, creating a gas flow pattern having a larger portion of purging gas flows between or near the substrates. With a larger portion of purging gas, compared to without the deflector 130, the purging gas can be more effectively removing foreign matters from the substrates. In some embodiments, the gas flow pattern can be a flowing pattern from the gas distributors 120 to one or more purging gas outlets 111 of the substrate container 100. In some embodiments, the gas flow pattern can be a flowing pattern from the gas distributors 120 to the front opening 110 of the substrate container 100.

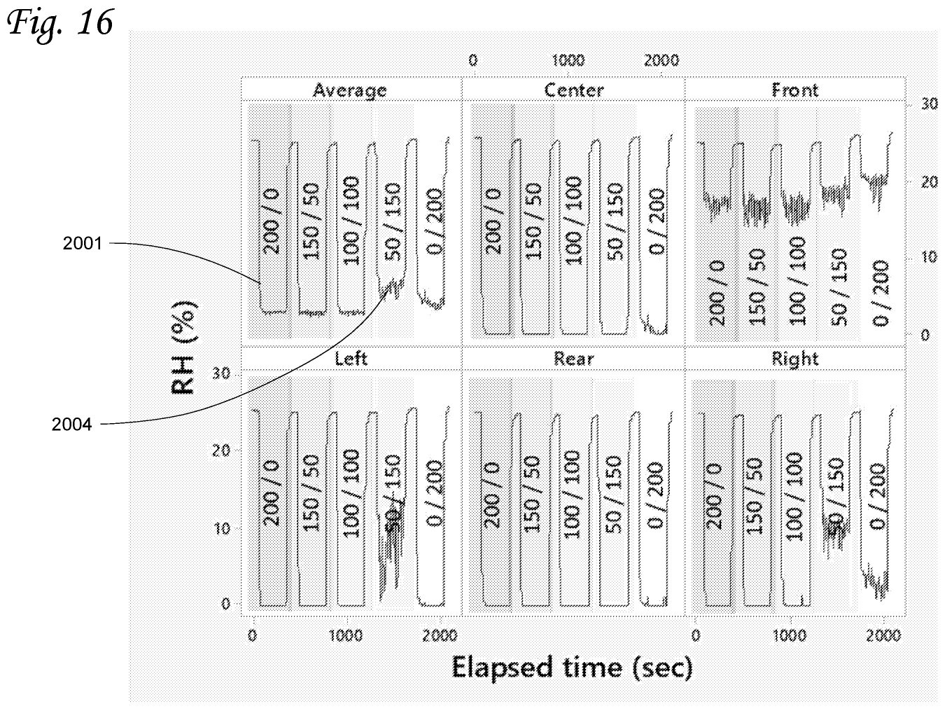

The purging efficacy can be measured by relative humidity (e.g., in percentages) within the substrate container 100 over time with a given flow rate of the purging gas provided to the gas distributors 120. For example, when a predetermined amount of purging gas is provided to the substrate container 100, the relative humidity measured within the substrate container 100 can be recorded and plotted over time as shown, for example, in FIG. 16. A plot of the substrate container 100 with the deflector 130 can be compared to a plot of the substrate container 100 without the deflector 130. The plot of the substrate container 100 without the deflector 130 can be a control for determining whether a deflector improves purging efficacy. When the plot of a substrate container 100 with a deflector 130 is compared with the control, a more rapid and/or consistent drop in relative humidity in the plot with the deflector 130 indicates improved purging efficacy. Non-limiting examples of a more rapid drop can include a larger drop in a unit of time, or a same amount of drop in a shorter amount of time, compared to that of the control. Non-limiting examples of a more consistent drop can be the relative humidity readings in a unit time having a smaller variance than that of the control.

Returning to FIG. 2A, in some embodiments, one or more of outlets 111 can be the front opening 110, for example, with the door opened. The door can be operated, for example opened or closed manually or automatically operated. The door can be operated by an operator, a robotic arm, or the like. The door can include one or more latches to engage with the substrate container 100. When closed, the door is configured to seal the substrate container 100 from the ambient around the substrate container 100 against foreign matters such as, but not limited to, moisture, dust particles, or the like. The door is removed in FIG. 2A to show the interior structure of the substrate container 100. The outlet 111 can connect the interior 140 of the substrate container 100 with an exterior of the substrate container 100 so that the purging gas, after flowing through the interior 140 of the substrate container 100 can be released from the substrate container 100. For example, the outlet 111 can be a one-way valve that allows purging gas to flow from the interior 140 to the exterior of the substrate container 100. In other embodiments, one or more of outlets 111 can be one or more purging gas outlets 111 disposed on the substrate container 100.

In some embodiments, the substrate container 100 can include one or more stabilizers 145. The stabilizers 145 can stabilize the gas distributor 120 and/or the deflector 130 to reduce movements of the gas distributor 120 and/or the deflector 130 relative to each other and/or relative to the substrate container 100. The stabilizers 145 can provide additional connections between the gas distributor 120, the deflector 130, and/or the substrate container 100. In some examples, the additional connections can rigidly connect the gas distributor 120, the deflector 130, and/or the substrate container 100 together to reduce relative movements. Movements can change the relative position between the gas distributor 120, the deflector 130, and/or the substrate container 100. The relative position could have been optimized to create the most effective flow pattern having the highest purging efficacy in a particular substrate or a particular purging process. Movements that changes the relative position can change the flow pattern, and reduce the purging efficacy. By including a stabilizer 145 reducing or limiting the movements, the relative position can be unchanged to maintain the flow pattern that optimizes the purging efficacy.

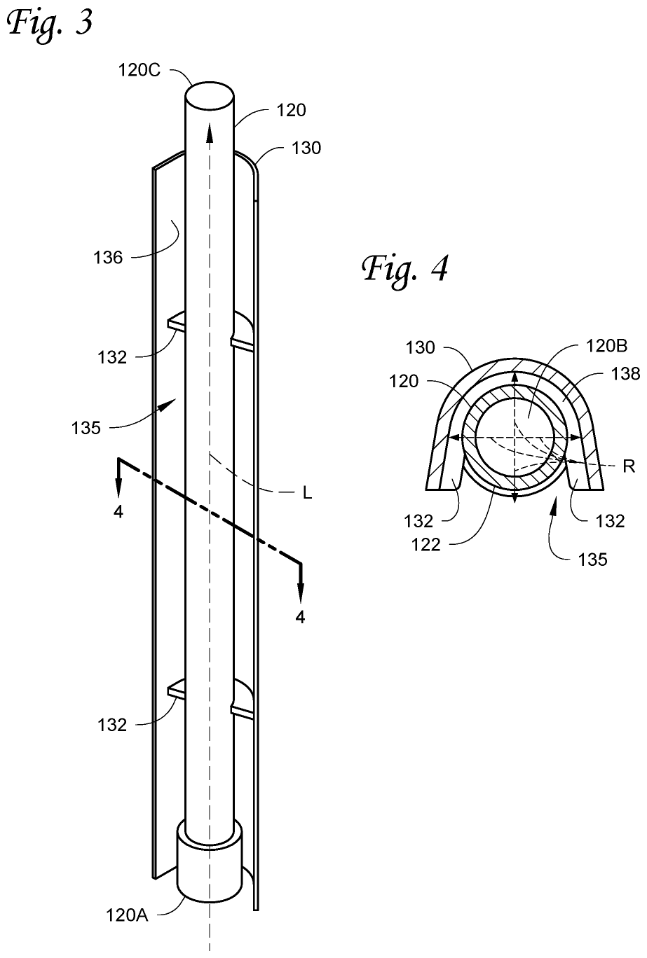

FIG. 3 shows a perspective view of the gas distributor 120 and the deflector 130, according to one or more example embodiments of a purging gas amplifier. FIG. 4 shows a cross-sectional view of the gas distributor 120 and the deflector 130, according to, e.g., the example embodiment of FIG. 3. The cross-sectional view shown in FIG. 4 is taken along a line 4-4 in FIG. 3.

As shown in FIGS. 3 and 4, the deflector 130 engages with the gas distributor 120. The gas distributor 120 can be configured to provide a purging gas to purge the interior 140 of the substrate container 100 as shown, for example, in FIG. 1. The gas distributor 120 can distribute the purging gas in a longitudinal direction L relative to the gas distributor 120. The gas distributor 120 can be a nozzle, a diffuser, or the like. In some embodiments, the gas distributor 120 can be an elongated member. The gas distributor 120 can protrude from and into the substrate container 100.

In the illustrated embodiment, the gas distributor 120 can be a diffuser having a porous body. A first end 120A of the gas distributor 120 can be fluidly connected to a purging gas source 190, for example, via the purging gas inlet 125 (shown in FIG. 1). The purging gas source 190 can provide a stream of purging gas (e.g., cleaned and dried air) to flow through the porous body in the longitudinal direction L. The porous body can include a channel 120B in the longitudinal direction L to distribute the purging gas in the longitudinal direction L. After being distributed in the channel 120B, the purging gas can then flow radially through the porous body, in radial directions R, to be released into the interior 140 of the substrate container 100. In some embodiments, the purging gas can flow radially through an outer surface 122 of the gas distributor 120 in radial directions R to be released into the interior 140 of the substrate container 100.

In some embodiments, a second end 120C of the diffuser can be capped. For example, the channel 120B can extend in the longitudinal direction L short of the second end 120C so that pressure of the purging gas can build up in the channel 120B before the purging gas flowing through the porous body in the radial directions R. In some embodiments, the pressure of the purging gas can build up in the channel 120B before the purging gas flowing through the second end 120C of the porous body.

The deflector 130 has a longitudinal opening 135 and a deflection surface 136. The longitudinal opening 135 and the deflection surface 136 can collectively guide a purging gas to flow in a predetermined direction by controlling a flow direction of at least a portion of the purging gas leaving the gas distributor 120. The predetermined direction can be based on desired flow through the substrate container 100. The deflector 130 can be positioned and/or oriented such that the flow is directed in the predetermined direction. The deflector 130 can be oriented such that the longitudinal opening 135 is centered on a line connecting the gas distributor 120 and a center of the substrate container 100. The deflector 130 can be a curved structure disposed to direct and/or deflect the purging gas flowing in the interior 140 of the substrate container 100. In some embodiments, the deflector 130 can be a non-permeable and/or non-porous material to the purging gas. For example, the deflector 130 can be made with plastic, metal, or the like.

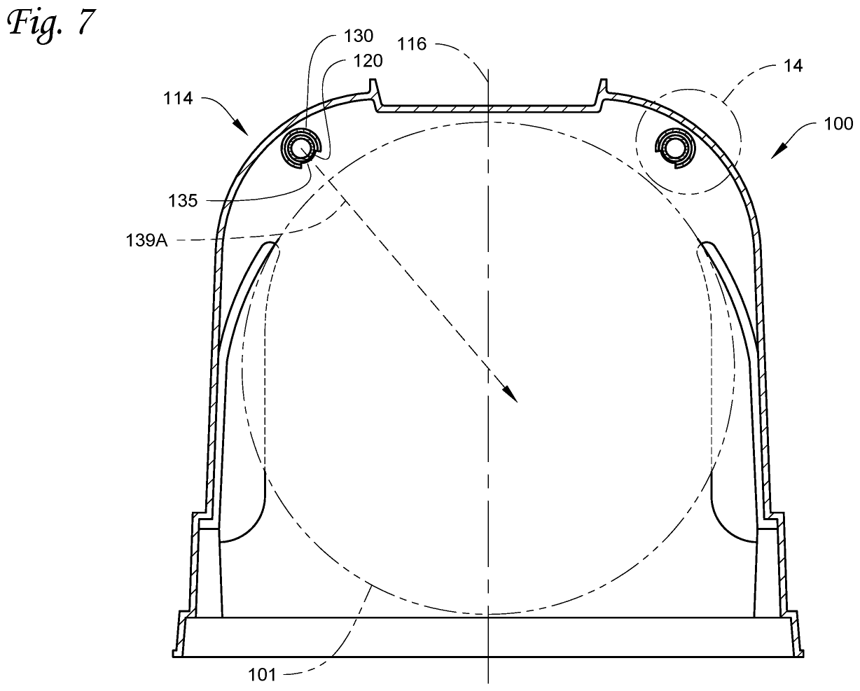

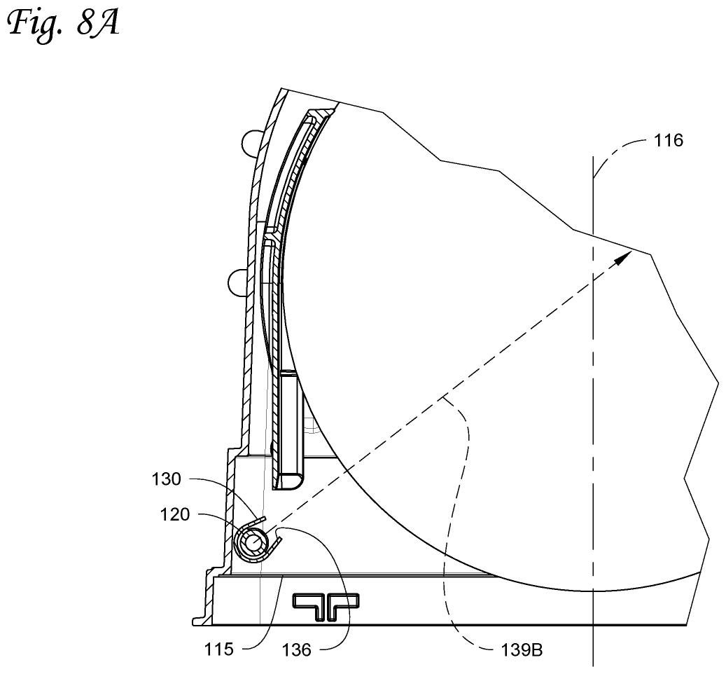

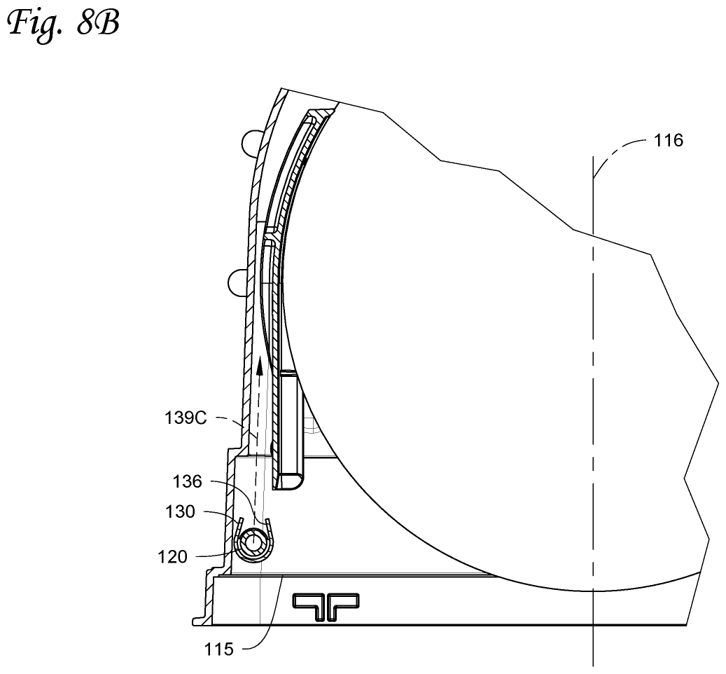

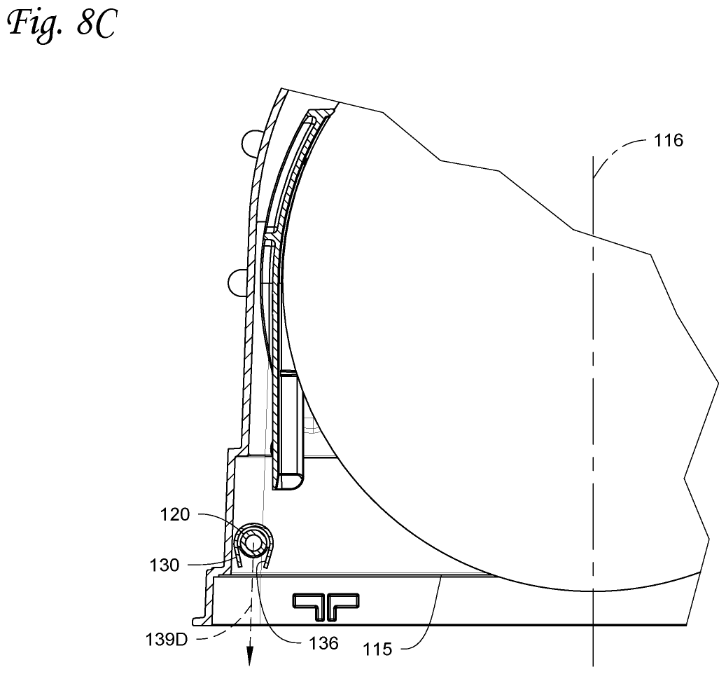

In some embodiments, the deflection surface 136 faces the gas distributor 120 to deflect the flow of the purging gas exiting the gas distributor 120 toward a center of the substrate container 100, away from the center of the substrate container 100, or at an angle relative to the centerline 116 of the substrate container 100 as further discussed with respect to FIGS. 7-8C.

In some embodiments, the gas distributor 120 can release the purging gas into the interior 140 of the substrate container 100. At least a portion of the purging gas from the gas distributor 120 flows into a gap 138 formed between the gas distributor 120 and the deflector 130. At least a portion of the purging gas in the gap 138 flows through the longitudinal opening 135. In some embodiments, the deflector 130 is spaced apart radially the gas distributor 120 to form the gap 138. In some embodiments, the gap 138 between the gas distributor 120 and the deflection surface 136 is 0.5 to 3 millimeters. In some embodiments, the gap 138 between the gas distributor 120 and the deflection surface 136 is in a range from 1 to 2 millimeters. In some embodiments, the gap 138 between the gas distributor 120 and the deflection surface 136 vary along the longitudinal direction L. In some embodiments, the gap 138 is smaller toward the second end 120C and larger toward the first end 120A of the gas distributor 120.

In some embodiments, the deflector 130 engages with the gas distributor 120. The deflector 130 is indexed to the gas distributor 120 by an indexer to maintain a relative angular position between the gas distributor 120 and the deflector 130 and/or the deflection surface 136. The indexer can be one or more features or structures that can maintain a relative angular or rotational position in a repeatable manner, for example, by rotating the gas distributor 120 in discrete angles. In some embodiments, movements of the substrate container 100 or fluid flows in the interior 140 of the substrate container 100 can influence the deflector 130 or the gas distributor 120 relative to the substrate container 100. It is appreciated that fluid can include any substance that is capable of flowing, including, but not limited to, a gas, a liquid, or the like. Non-limiting examples of the fluid can include the purging gas, a cleaning solutions, or the like. The influence can result in, but not limited to, a change in relative angular position between, for example, the deflector 130 and the substrate container 100. The indexer can maintain the relative angular position by resisting a force that may move or rotate the gas distributor 120 or the deflector 130 relative to the substrate container 100 by providing a connection. The connection can be between the deflector 130 and the gas distributor 120, the deflector 130 and the substrate container 100, or the gas distributor 120 and the substrate container 100. In some embodiments, the connection can be among the gas distributor 120, the deflector 130, and the substrate container 100. In some embodiments, the connection is rigid to resist or dissipate the force that may move or rotate the gas distributor 120 or the deflector 130 relative to the substrate container 100. In some embodiments, the deflector 130 can directly or indirectly engage with gas distributor 120 via the indexer forming, for example, an interference fit, a snap-fit, a clip mechanism, or the like, creating friction between the deflector 130 and gas distributor 120 to resist the influence.

In some embodiments, one or more ribs 132 can be an embodiment of the indexer. The ribs 132 can engage with the gas distributor 120 to attach the deflector 130 to the gas distributor 120, for example, by an interference fit, a snap-fit, a clip mechanism, or the like. The ribs 132 extends from the deflection surface 136 of the deflector 130. A distal end 134 of the ribs 132 engages with an outer surface 122 of the gas distributor 120 such that a relative angular position between the gas distributor 120 and the deflector 130 and/or the deflection surface 136 is maintained. The influence can result in, but not limited to, a change in relative angular position between, for example, the deflector and the substrate container. In some embodiments, movements of the substrate container 100 or fluid flows in the interior 140 of the substrate container 100 can influence the deflector 130 or the gas distributor 120 relative to the substrate container 100. The ribs 132 can maintain the relative angular position by resisting a force that may move or rotate the gas distributor 120 or the deflector 130 relative to the substrate container 100 by providing a connection. The connection can be between the deflector 130 and the gas distributor 120 via the ribs 132. In some embodiments, the connection is rigid to resist or dissipate the force that may move or rotate the gas distributor or the deflector relative to the substrate container. The ribs 132 can create the connection and maintain the relative angular position by, for example, the ribs 132 forming an interference fit, a snap-fit, a clip mechanism, or the like, between the deflector 130 and the gas distributors by creating friction between the ribs 132 and the gas distributor 120 to resist the influence. In some embodiments, the one or more ribs 132, or an indexer, attaching the diffuser 130 to the gas distributor 120 can be a diffuser-deflector assembly.

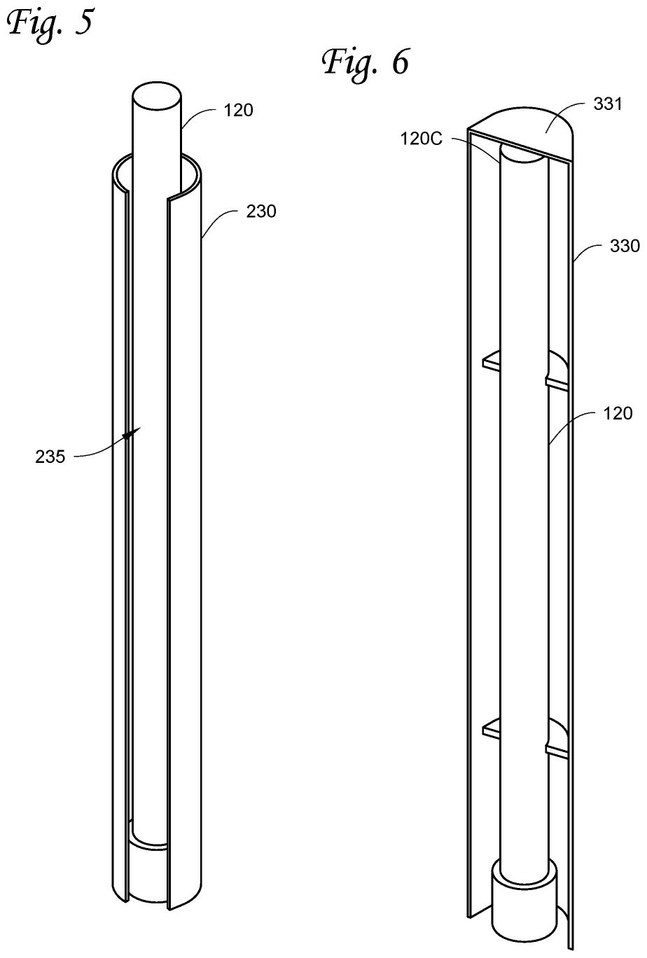

FIG. 5 shows a gas distributor 120 and a deflector 230, according to one or more example embodiments of a purging gas amplifier. Compared to the deflector 130 of, for example, FIG. 4, the deflector 230 is a focused deflector by having a longitudinal opening 235 narrower than the longitudinal opening 135. The longitudinal opening 235 being narrower can affect the gas flow pattern by accelerating a linear velocity of the purging gas exiting the deflector 230 and with more directional control of the purging gas leaving the deflector 240.

FIG. 6 shows a gas distributor 120 and a deflector 330, according to one or more example embodiments of a purging gas amplifier. Compared to the deflector 130 of, for example, FIG. 4, the deflector 330 includes a lid 331. The lid 331 of the deflector 330 can be disposed over the second end 120C of the gas distributor 120. The lid 331 can deflect the purging gas leaving the gas distributor 120 in the longitudinal direction L toward the radial direction R (as shown in FIG. 4).

FIG. 7 is a cross-sectional view of the substrate container 100, according to one or more example embodiments of a purging gas amplifier. As shown in FIG. 7, the substrate container 100 includes the gas distributor 120 engaged with the deflector 130 disposed in the shoulder volume 114 of the substrate container 100. The longitudinal opening 135 deflects the purging gas leaving the deflector 130 along a direction 139A. An angle between the direction 139A and a centerline 116 can be between 0° to 80°. In some embodiments, the angle can be between 15° to 25°. The direction 139A can be determined according to the application, for example, for different sizes and/or placements of substrates stored therein, for different compositions, temperatures, pressures, flow rates, or the like, of purging gas.

FIG. 8A is a partial cross-sectional view of the substrate container 100, according to one or more example embodiments of a purging gas amplifier. Compared to the substrate container 100 of FIG. 7, the substrate container 100 of FIG. 8A includes the gas distributor 120 disposed in the lip volume 115 of the substrate container 100. The deflector 130 engages with the gas distributor 120 and directs the purging gas exiting the deflector 130 toward a direction 139B. An angle between the direction 139B and the centerline 116 can be any angles, for example, between 0° to 80°. In some embodiments, the angle can be between 15° to 25°. The direction 139B can be determined according to the application, for example, for different sizes and/or placements of substrates stored therein, for different compositions, temperatures, pressures, flow rates, or the like, of purging gas.

FIG. 8B a partial cross-sectional view of the substrate container 100, according to one or more example embodiments of a purging gas amplifier. Compared to the substrate container 100 of FIG. 8A, the deflector 130 is arranged to direct the purging gas exiting the deflector 130 toward a direction 139C. The direction 139C can be parallel to the centerline 116 and directing away from the lip volume 115 such that the deflector 130 is directing the purging gas toward the back 112 of the substrate container 100.

FIG. 8C a partial cross-sectional view of the substrate container 100, according to one or more example embodiments of a purging gas amplifier. Compared to the substrate container 100 of FIG. 8A, the deflector 130 is arranged to direct the purging gas exiting the deflector 130 toward a direction 139D. The direction 139D can be parallel to the centerline 116 and directing toward the lip volume 115 such that the deflector 130 is directing the purging gas toward the front opening 110 of the substrate container 100.

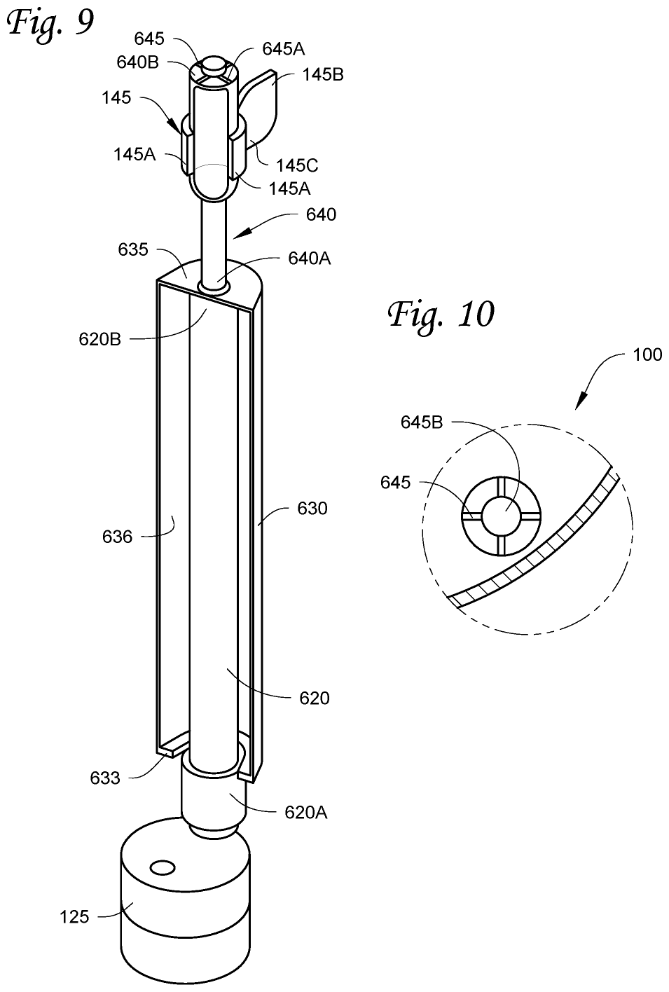

FIG. 9 is a perspective view of a gas distributor 620 and a deflector 630, according to one or more example embodiments of a purging gas amplifier. FIG. 10 shows a schematic view of a mating surface 100A on the substrate container 100, according to the example embodiment of FIG. 9. FIG. 10 can be a detailed view at location 14 (shown in FIG. 7) taken from the interior 140 of the substrate container 100 toward the top side 108 of the substrate container 100. In some embodiments, a first joint member 645A shown in FIG. 9 mates with a second joint member 645B shown in FIG. 10 to form a spline joint.

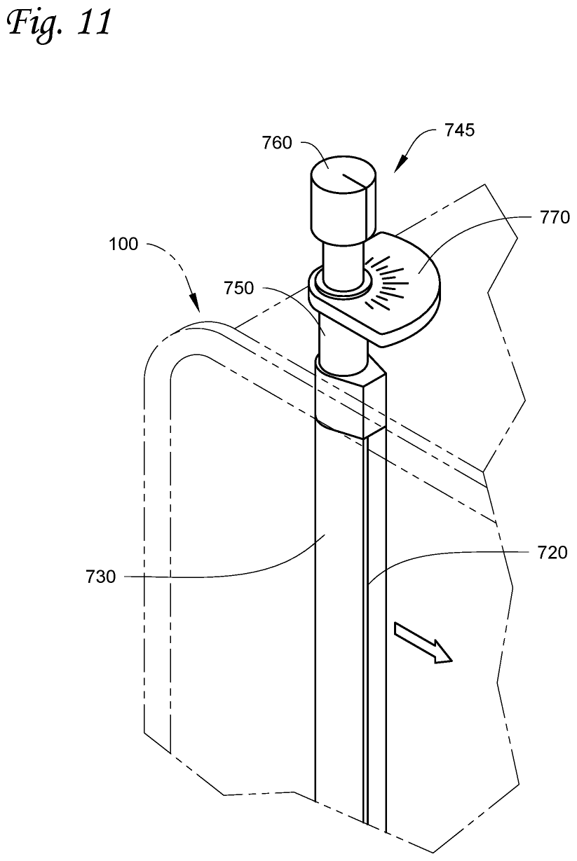

As shown in FIGS. 9 and 10, the gas distributor 620 is an elongated member having a first end 620A and a second end 620B. The first end 620A can be fluidly connected to the purging gas inlet 125 that supplies purging gas to the gas distributor 620 to be distributed in the substrate container 100 (shown in FIG. 11).

The deflector 630 can engage with the gas distributor 620 to deflect purging gas leaving the gas distributor 620. The deflector 630 can be an elongated member having a rib 633 disposed on one end and a lid 635 disposed on the other end. The rib 633 can attach to the first end 620A of the gas distributor 620, for example, by an interference fit, a snap-fit, a clip mechanism, or the like. The lid 635 can attach to the second end 620B by, for example, one or more fasteners, adhesives, clips, or the like.

It is appreciated that the deflector 630 can engage with the gas distributor 620 by one or more structures so long as a relative angular position between the deflector 630 and the gas distributor 620 can be maintained. In some embodiments, when the deflector 630 engages with the gas distributor 620 by an indexer. The deflector 630 is indexed to the gas distributor 620 by the indexer to maintain a relative angular position between the gas distributor 620 and the deflector 630 and/or the deflection surface 636. In some embodiments, movements of the substrate container 100 or fluid flows in the interior 140 of the substrate container 100 can influence the deflector 630 or the gas distributor 620 relative to the substrate container 100. The influence can result in, but not limited to, a change in relative angular position between, for example, the deflector 630 and the substrate container 100. The indexer can maintain the relative angular position by resisting a force that may move or rotate the gas distributor 620 or the deflector 630 relative to the substrate container 100 by providing a connection. The connection can be between the deflector 630 and the gas distributor 620, the deflector 630 and the substrate container 100, or the gas distributor 620 and the substrate container 100. In some embodiment, the connection can be among the gas distributor 620, the deflector 630, and the substrate container 100. In some embodiments, the connection is rigid to resist or dissipate the force that may move or rotate the gas distributor 620 or the deflector 630 relative to the substrate container 100. In some embodiments, the deflector 630 can directly or indirectly engage with gas distributor 620 via the indexer forming, for example, an interference fit, a snap-fit, a clip mechanism, or the like, creating friction between the deflector 630 and gas distributor 620 to resist the influence.

The stabilizer 640 can be disposed on the deflector 630 and/or the gas distributor 620 to stabilize the deflector 630 and/or the gas distributor 620. The deflector 630 and/or the gas distributor 620 can be stabilized when the deflector 630 and/or the gas distributor 620 is shorter or substantially shorter than an internal height of the substrate container 100. In some embodiments, the internal height can be a distance between the bottom side 106 and the top side 108 (shown in FIG. 1). The stabilizer 640 can stabilizes, for example, by providing a connection to the substrate container 100.

The stabilizer 640 can include a first end 640A and a second end 640B. In some embodiments, the first end 640A of the stabilizer 640 can be engaged with to the second end 620B of the gas distributor 620 and/or the deflector 630. The second end 640B of the stabilizer 640 can be engaged with the substrate container 100 (shown in FIG. 1). In some embodiments, the second end 640B of the stabilizer 640 can be engaged with the first lateral side 102, the second lateral side 104, the bottom side 106, the top side 108, and/or the back 112 of the substrate container 100.

The stabilizers 640 can stabilize the gas distributor 620 and/or the deflector 630 to reduce movements of the gas distributor 620 and/or the deflector 630 relative to each other and/or relative to the substrate container 100. The stabilizers 640 can provide additional connections between the gas distributor 620, the deflector 630, and/or the substrate container 100. In some examples, the additional connections can rigidly connect the gas distributor 620, the deflector 630, and/or the substrate container 100 together to reduce relative movements. Reducing movements can stabilize the gas distributor 620 and/or the deflector 630 relative to the substrate container 100 so that, for example, variances in purging performance caused by the relative positions between the gas distributor 620, the deflector 630, and/or the substrate container 100 can be reduced. Movements can change the relative position between the gas distributor 620, the deflector 630, and/or the substrate container 100. The relative position could have been optimized to create the most effective flow pattern having the highest purging efficacy in a particular substrate or a particular purging process. Movements that changes the relative position can change the flow pattern, and reduce the purging efficacy. By including a stabilizer 640 reducing or limiting the movements, the relative position can be unchanged to maintain the flow pattern that optimizes the purging efficacy.

In some embodiments, the stabilizer 640 can be part of an indexer 645 to maintain a relative angular position between the gas distributor 620 and the stabilizer 640, or the deflector 630 and the stabilizer 640. The indexer 646 can be a spline joint having a first joint member 645A and a second joint member 645B. The first joint member 645A and a second joint member 645B can engage with each other in one or more relative angular positions and maintain the angular position. In some embodiments, movements (e.g., moving of the substrate container 100 between equipment) or fluid flows (e.g., flowing streams of purging gas, cleaning solution, etc.) near the deflector 630 can push the deflector 630 and result in a force rotating the deflector 630 relative to the gas distributor 620. The indexer 645 can maintain the relative angular position by, for example, by friction between the indexer 645 and the gas distributor 620, resisting the force. In some embodiments, the first joint member 645A is disposed on the second end 640B of the stabilizer 640. The second joint member 645B is disposed on the substrate container 100.

In some embodiments, the first joint member 645A is a male member disposed to mate with the second joint member 645B being a female member. The first joint member 645A can include a pattern and/or protrusions extending outward to mesh with a pattern and/or recesses indented into the second joint member 645B so that the first joint member 645A and the second joint member 645B can mate at one or more relative angular positions. In some embodiments, the first joint member 645A is engaged with the second joint member 645B, for example, by springs, interference fit, friction fit, or the like.

In some embodiments, the stabilizer 640 can optionally or alternatively engage with the stabilizer 145 (also shown in FIG. 1). As discussed in FIG. 1, the stabilizer 145 can stabilize the gas distributor 120 and/or the deflector 130. Compared to the embodiment of FIG. 1, the gas distributor 620 and the deflector 630 are shorter than the gas distributor 120 and/or the deflector 130. The stabilizer 640 can function as an extender or an adaptor allowing the gas distributor 620 and the deflector 630 to engage with, and be stabilized by, the stabilizer 145 as arranged in the substrate container 100 according to the illustration of FIG. 1. It is appreciated that, by including the stabilizer 640, the gas distributor 620 and the deflector 630 can replace the gas distributor 120 and the deflector 130 in the embodiment of the substrate container 100 as illustrated in FIG. 1.

The stabilizer 145 can include a first end 145A rigidly that is attached to a second end 145B by a stabilizer body 145C. The first end 145A can be a c-shaped clip attaching to the stabilizer 640 by wrapping at least partially around the stabilizer 640, gripping the stabilizer 640. The second end 145B can engage with the substrate container 100 by any attachment means, such as adhesive, fastener, welding, clips, interference fit, etc.

FIG. 11 shows an indexer 745, according to one or more example embodiments of a purging gas amplifier. As shown in FIG. 11, the substrate container 100 includes a gas distributor 720 and a deflector 730. An indexer 745 connected directly or indirectly to the gas distributor 720 and/or the deflector 730 to maintain a relative angular position between the gas distributor 720 and the deflector 730 or a deflection surface of the deflector 730. It is appreciated that the gas distributor 720 and the deflector 730 can be any of the gas distributors and the deflectors, respectively, as described in FIGS. 1-14.

The indexer 745 extends through the substrate container 100 so that the indexer 745 can be adjusted from the outside of the substrate container 100. For example, the relative angular position between the gas distributor 720 and the deflector 730 or a deflection surface of the deflector 730 can be changed by a force turning the indexer 745 from an exterior of the substrate container 100 to change the relative angular position from a first angle to a second angle. It is appreciated that the indexer 745 can extend through the top side 108 and/or the bottom side 106 (shown in FIG. 1) of the substrate container 100 such that the indexer can be adjusted from the top and/or the bottom side of the substrate container 100 by a user, a robotic arm, or the like.

In some embodiments, the indexer 745 includes a first member 750 and a second member 770. The first member 750 can include a nob 760 disposed on an exterior of the substrate container 100. In some embodiments, the nob 760 can connect to the first member 750, for example, by one or more fasteners, welding, adhesive, interference fit, or the like or by formed from the same piece of material. The first member 750 can engage with the second member 770 and/or the substrate container 100, for example, by a loaded spring pushing the first member 750 against the second member 770 and/or the substrate container 100.

When a force is asserted onto the indexer 745, for example, by turning the first member 750, the indexer 745 can move from a first angle. The force can turn the indexer 745 to a second angle. When the force is removed, the indexer 745 stays at the second angle. When the force asserted, for example, by a user or a robotic arm turning the indexer 745, is removed, the indexer maintains the relative angular position at the second angle. In some embodiments, the force can be asserted onto the first member 750 through the nob 760.

In some embodiments, the force turning the indexer 745 can be applied by a user or a robotic arm. The second member 770 can be marked so that a user can turn the deflector 730, by turning the indexer 745, from an outside of the substrate container 100 in a repeatable manner. The first member 750 can be engaged with a robotic arm that turns the indexer 745 to change the relative angular position between the deflector 730 and the gas distributor 720, for example, during substrate production. In some embodiments, the nob 760 can be turned by a robotic arm controlling (e.g., turning or maintaining) the angular position through a servo motor. In some embodiments, a second member 770 can be a marked tab 770 can connect to the substrate container 100 and independent from the rotational movements of the nob 760. The marked tab 770 can be marked with angular positions, for examples, 0-80 degrees from a reference point. The nob 760 can thereby turned repetitively to a particular angular position by visual referencing to the marked tab 770.

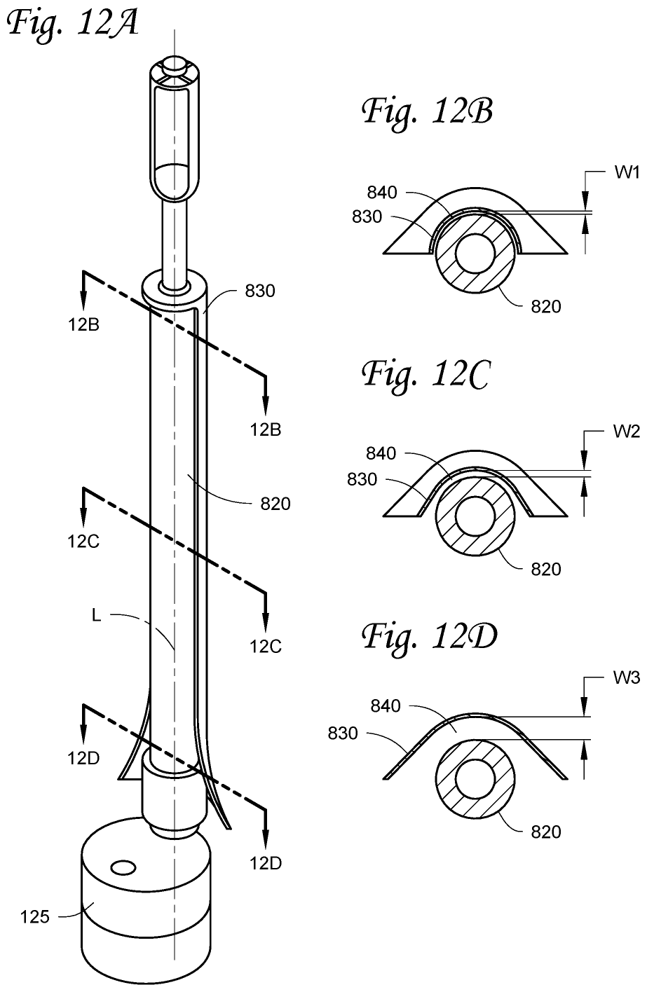

FIG. 12A shows a perspective view of a gas distributor 820 and a deflector 830, according to one or more example embodiments of a purging gas amplifier. FIG. 12B shows another cross-sectional view of the gas distributor 820 and the deflector 830, according to the example embodiment of FIG. 12A. FIG. 12C shows yet another cross-sectional view of the gas distributor and the deflector, according to the example embodiment of FIG. 12A. FIG. 12D shows yet another cross-sectional view of the gas distributor and the deflector, according to the example embodiment of FIG. 12A. The cross-sectional view shown in FIG. 12B can be taken along a line 12B-12B in FIG. 12A. The cross-sectional shown in FIG. 12C can be taken along a line 12C-12C in FIG. 12A. The cross-sectional view shown in FIG. 12D can be taken along a line 12D-12D in FIG. 12A. It is appreciated that the gas distributor 820 and a deflector 830 and be any of the distributors and the deflectors, respectively, as shown in FIGS. 1-15. A gap 840 is between the gas distributor 840 and a deflection surface of the gas deflector 830 varies along the longitudinal direction L. In the illustrated example, a width of the gap 84f0 is expanding from W1 to W2 and W3 along the longitudinal direction L.

FIG. 13 shows a cross-sectional view of the substrate container 100, according to one or more example embodiments of a purging gas amplifier. The cross-sectional view shown in FIG. 13 can be taken along the line 2-2 of FIG. 1 to illustrate examples of locations where the gas distributors 120 and the deflectors 130 can be installed within the substrate container 100. It is appreciated that the gas distributors 120 and the deflectors 130 can be disposed anywhere in the substrate container 100 and outside the interior volume 101 that can be occupied by the substrates. In some embodiments, the gas distributors 120 and the deflectors 130 are arranged in a manner that does not interfere with the insertion and/or removal of the substrates. For example, the gas distributors 120 and the deflectors 130 can be arranged to be spaced apart over a distance that is larger than a diameter of the substrates designed to be placed within the substrate container 100 so that the substrates can be inserted or removed without contacting with or having to remove the gas distributors 120 and the deflectors 130. As shown in FIG. 13, one or more gas distributors 120 can be disposed in substrate container 100. As non-limiting examples, the gas distributors 120 can be positioned in any of exemplary locations of H1-H5, and H8 within the substrate container 100. As illustrated in FIG. 13, location H1 is disposed in the rear end of the interior 140 of the substrate container 100. The locations H3 are disposed in the shoulder volume 114 of the substrate container 100. The locations H5 are disposed in the lip volume 115 of the substrate container 100. The location H8 is disposed across the lip volume 115 and over the front opening 110 of the substrate container 100. In some embodiments, the location H8 is disposed on the top side 108 (shown in FIG. 1) of the substrate container 100. It is appreciated that the one or more gas distributors disposed at H1-H5 can be disposed vertically relative to the substrates. In some embodiments, the gas distributor 120 and the deflector 130 of FIG. 1 can be referred to as disposed vertically relative to the substrate container 100. In some embodiments, the gas distributor and/or deflector disposed at H8 can be disposed horizontally relative to the vertically disposed gas distributors (e.g., the gas distributor 120 and the deflector 130 of FIG. 1).

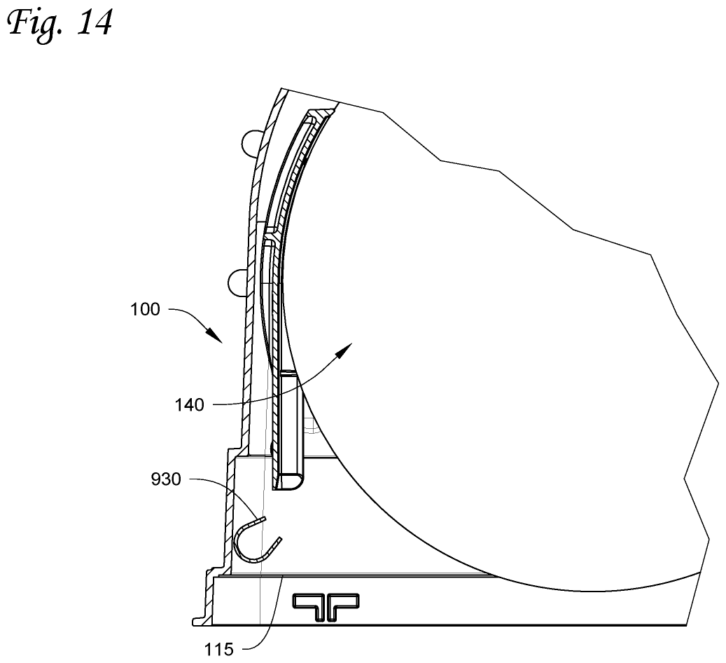

FIG. 14 shows a cross-sectional view of a deflector 930 disposed in the substrate container 100, according to one or more example embodiments of a purging gas amplifier. The deflector 930 can be any one of the deflectors shown in FIGS. 1-16. In the illustrated example, the deflector 930 is disposed in the lip volume 115 of the substrate container 100. The deflector 930 can have an elongated body to direct the gas flow pattern of the purging gas from a gas distributor to an outlet of the substrate container 100 in the interior 140 of the substrate container 100 to improve purging efficacy. The purging gas can be provided to the interior 140 of the substrate container 100 from one or gas distributors and/or purging gas inlets disposed elsewhere in the interior 140 of the substrate container 100. Compared to, for example, the deflector 130 of FIG. 1, the deflector 930 is an empty deflector such that the deflector 930 is disposed in the substrate container 100 to deflect a gas flow pattern of the purging gas in the substrate container 100, without engaging with a gas distributor, while a gas distributor can be disposed elsewhere in the substrate container 100. In some embodiments, the deflector 930 is not engaged with or disposed over a gas distributor. In some embodiments, the deflector 930 is not disposed over a purging gas outlet or disposed over a purging gas outlet not but disposed to not supply any purging gas. In some embodiments, the deflector 930 can be disposed at or near H5 (shown in FIG. 13) to direct the gas flow pattern of the purging gas to improve purging efficacy.

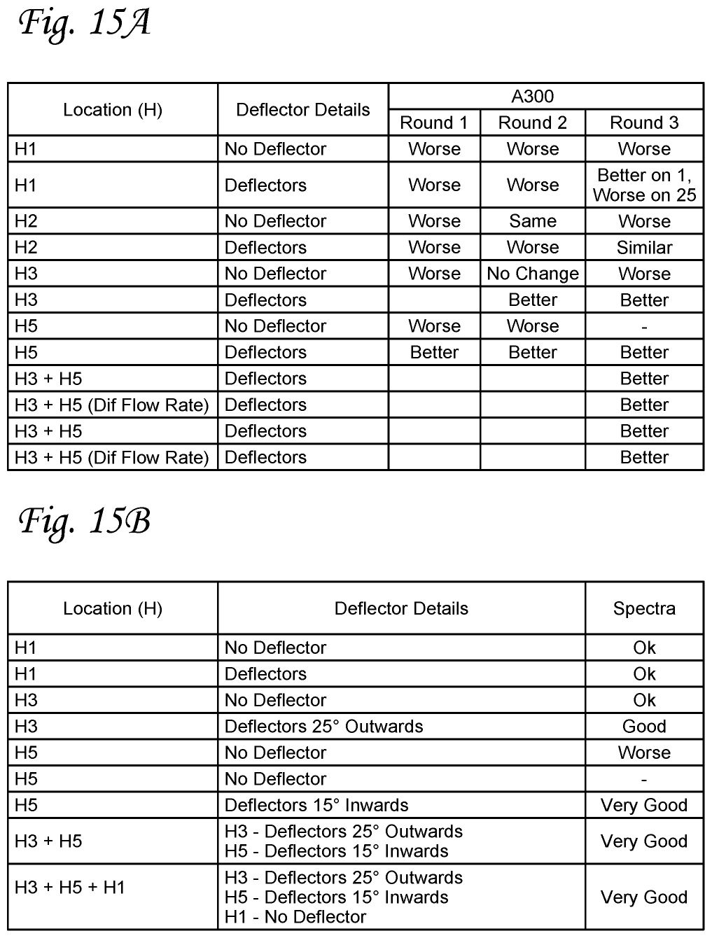

FIG. 15A is a table summarizing experimental results of gas distributors and deflectors that improve purging efficacy, according to one or more example embodiments of a purging gas amplifier. The experiments of FIG. 15A are conducted in a substrate container having a tradename of A300 made by ENTEGRIS™. Gas distributors with and without deflectors are disposed in locations H1, H2, H3, H5, and H3 and H5. As shown in the summary, gas distributors with deflectors disposed at locations H3, H5, or H3 and H5 consistently performed better than or improved upon the same substrate container without the gas distributors with deflector installed at the location at a predetermined purging gas flow rate. Particularly, when gas distributors and deflectors are disposed on both H3 and H5 positions, purging efficacy is constantly improved at different flow rates of purging gas.

FIG. 15B is a table summarizing experimental results of gas distributors and deflectors that improve purging efficacy, according to one or more example embodiments of a purging gas amplifier. The experiments of FIG. 15B are conducted in a substrate container having a tradename of SPECTRA™ made by ENTEGRIS™. Gas distributors with and without deflectors are disposed in locations H1; H3; H5; H3 and H5; and H1, H3, and H5. As shown in the summary, gas distributors with deflectors disposed at locations of H3; H5; H3 and H5; and H1 (without a gas distributor), H3 and H5 performed better than or improved upon the same substrate container without the gas distributors with deflector installed at the location at a predetermined purging gas flow rate.

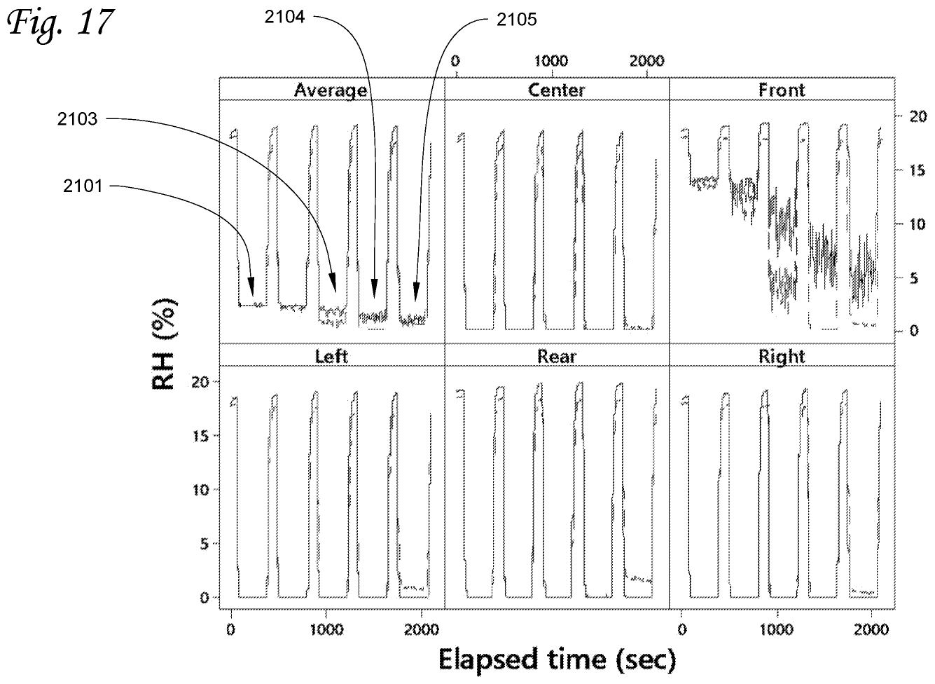

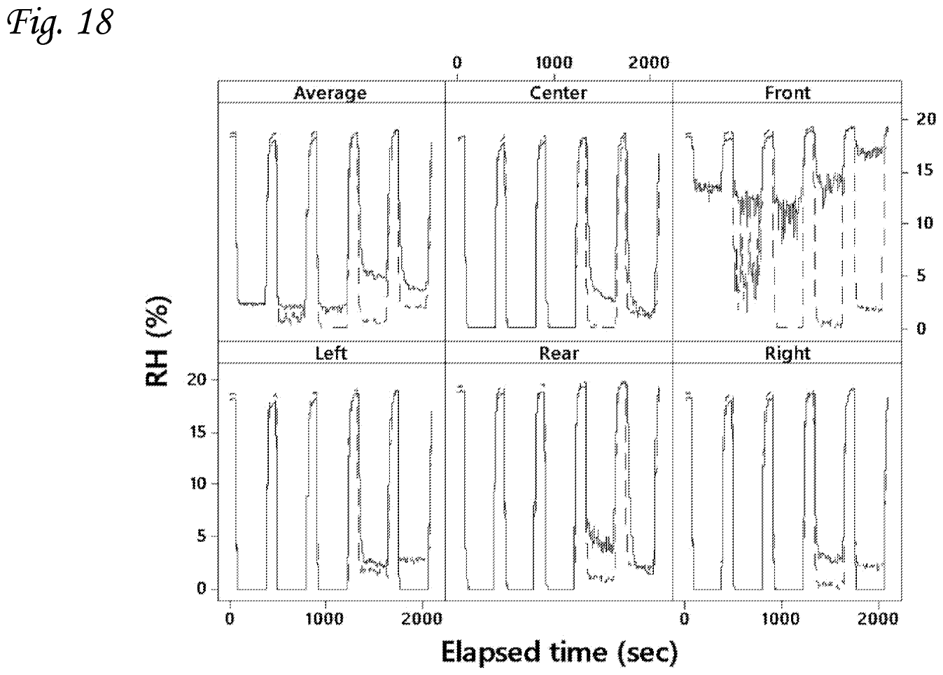

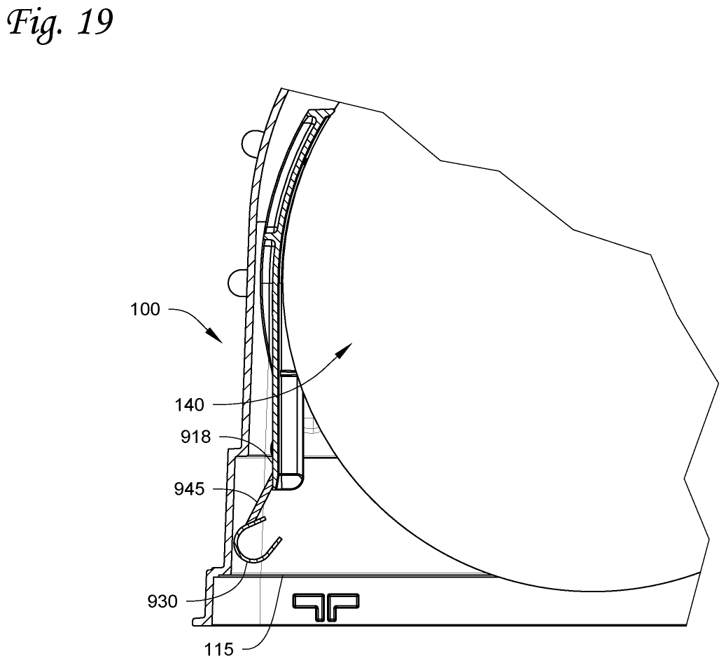

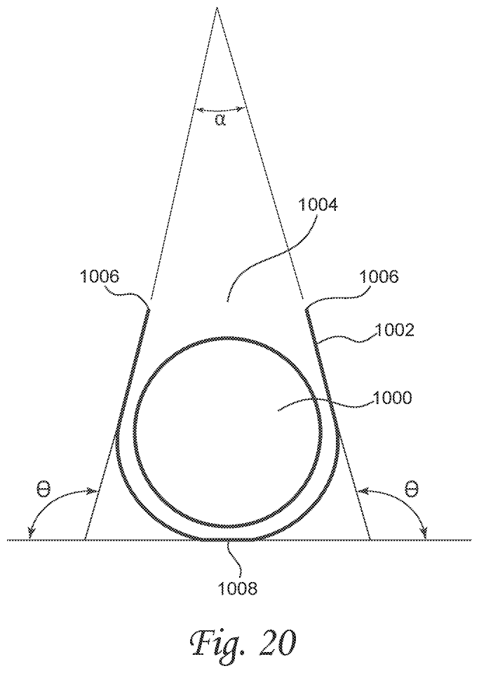

FIG. 16 shows a test method of a substrate container having one or more gas distributors and deflectors disposed therein, according to one or more example embodiments of a purging gas amplifier. FIGS. 17-18 show test results of a substrate container having one or more gas distributors and deflectors disposed therein, according to one or more example embodiments of a purging gas amplifier.

Purging efficacy is shown by a drop in relative humidity inside the substrate container compared to a control. Experiments are conducted by supplying the substrate container with a predetermined flow rate of purging gas. In the experiment results shown in FIGS. 17-18, the flow rate is 200 Standard Liters Per Minute (SLPM). The purging gas is cleaned and dried air (CDA gas). The relative humidity is presented in percentages.

The 200 SLPM purging gas is provided into the substrate container in five distributions via a conventional diffuser and/or an embodiment of gas distributors and/or deflectors as shown and described in any of FIGS. 1-16 above.

The five distributions are (1) 200 SLPM to the conventional diffusers and 0 SLPM to the embodiment of gas distributors with or without deflectors; (2) 150 SLPM to the conventional diffusers and 50 SLPM to the embodiment of gas distributors with or without deflectors; (3) 100 SLPM to the conventional diffusers and 100 SLPM to the embodiment of gas distributors with or without deflectors; (4) 50 SLPM to the conventional diffusers and 150 SLPM to the embodiment of gas distributors with or without deflectors; and (5) 0 SLPM to the conventional diffusers and 200 SLPM to the embodiment of gas distributors with or without deflectors.

Purging efficacy with all the purging gas supplied to the conventional diffusers (i.e., 200 SLPM to diffusers and 0 SLPM to the embodiment of gas distributors with or without deflectors) is used as the control to evaluate purging efficacy by adding embodiments of gas distributors and/or deflectors disposed at varies locations within the substrate container. A quicker and/or larger relative humidity drop demonstrates a better or improved purging efficacy. For example, the distribution 2001 is better than the distribution 2004 because the relative humanity associated with the gas distribution of 2001 has a larger drop than that of the gas distribution of 2004.

The five distributions of purging gas are provided sequentially during the experiments such that the elapsed time on the y-axis dictates the flow rates distribution in FIGS. 17-18 as illustrated in FIG. 16. For example, at 2001 the first relative humidity drop happens when 200 SLPM is provided to diffusers and 0 SLPM is provided to embodiments of gas distributors with or without deflectors disposed at various locations within the substrate container (i.e., 200/0 shown in the chart).

The relative humidity at the center, front, left, rear, and right of the interior of the substrate container is measured and plotted with relative humidity RH (%), on the x-axis, and elapsed time (in seconds) on the y-axis. The numerical averages of the relative humidity obtained are presented under “average” to show the purging efficacy of the substrate container and suggest that the gas flow pattern of the purging gas is more effective and is improved upon the control. It is appreciated that an efficiency improvement in the gas flow pattern of the purging gas may also be shown by a decrease of a local relative humidity. A local relative humanity can be indicated by “Center”, “Front”, “Left”, “Rear”, or “Right” as shown in FIGS. 16-18.

It is appreciated that the charts in FIG. 16 are legends to illustrate the presentation of the experimental result of FIGS. 17-18. The charts in FIG. 16 are not experimental results of embodiments described in the present application.

FIG. 17 shows the experimental result of gas distributor disposed at H3 (shown in FIG. 13) and deflectors disposed at a 25° angle, according to one embodiment. Solid lines in FIG. 17 represent the relative humidity of the gas distributor disposed at H3 without a deflector. Dashed lines in FIG. 17 represent the relative humidity of the gas distributor disposed at H3 each with a deflector disposed at a 25° angle.

As shown in FIG. 17, including embodiments of gas distributors at H3 improves the purging efficacy because, for example, at 2105 (i.e., all 200 SLPM to gas distributors at H3), the relative humidity dropped lower than at 2101 (i.e., all 200 SLPM to diffuser as control). FIG. 17 further shows that having a deflector disposed on the gas distributor improves purging efficacy. For example, at 2103 and 2104, the dash line drops below the solid line showing a larger drop of relative humidity, and thus, having deflectors results in a better or more improved gas flow pattern and purging efficacy. The improvement is more pronounced at the front of the substrate container such that the relative humidity dropped more significantly when more purging gas is distributed to the gas distributors at H3 and the gas distributors at H3 with deflectors.

FIG. 18 shows the experimental result of gas distributors disposed at H5 (shown in FIG. 13) and deflectors disposed at a 15° angle, according to one embodiment. Solid lines in FIG. 18 represent the relative humidity of the gas distributor disposed at H5 without a deflector. Dashed lines in FIG. 18 represent the relative humidity of the gas distributor disposed at H5 each with a deflector disposed at a 15° angle.

FIG. 14B shows a cross-sectional view of a deflector 930 disposed in a substrate container 100, according to one or more example embodiments of a purging gas amplifier. Compared to the embodiment of FIG. 14A, a stabilizer 945 is included to stabilize the deflector 930. The stabilizer 945 can be a ridged member having a first end attaches to a leading end 918 of the shelf 118. A second end of the 945 can attach to the deflector 930 to stabilize the deflector 930. It is appreciated that the stabilizer 945 can attach to the deflector 930 and/or the leading end 918 of the shelf 118 by any attachment means, such as adhesive, fastener, welding, clips, interference fit, etc. It is appreciated that the stabilizer 945 any be arranged to stabilize any deflectors as disclosed herein and is not limited to stabilize a deflector 930 being an empty deflector.

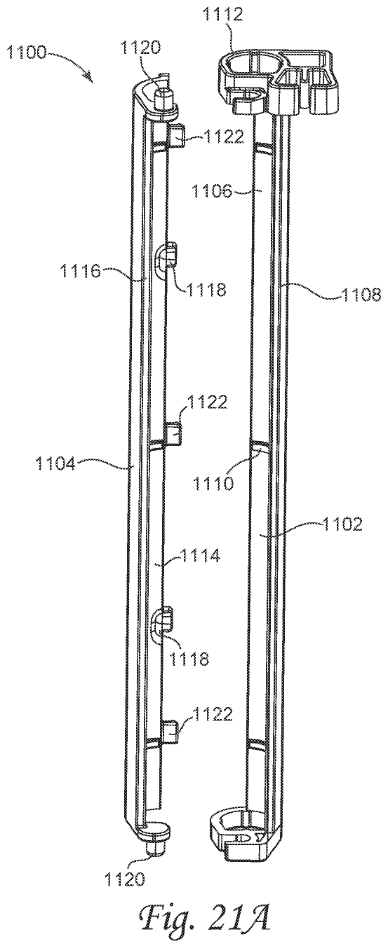

FIG. 20 shows a cross-sectional view of a diffuser and a deflector according to an embodiment. Diffuser 1000 is, e.g, a diffuser tower configured to allow a release of purge gas into a substrate container. Diffuser 1000 can be positioned within the substrate container at any suitable location, including, as non-limiting examples, any of H1-H5 described above and shown in FIGS. 15A and 15B.

Deflector 1002 is at least partially surrounds the diffuser 1000. Deflector 1002 includes an opening 1004 defined by deflector tips 1006. The opening 1004 is opposite to a back surface 1008 of the deflector 1002. The deflector tips 1006 are angled towards one another to define an opening angle a as shown in FIG. 20. In an embodiment, the opening angle a can be an acute angle that can allow opening 1004 to operate as a nozzle, providing directional specificity to the flow provided by diffuser 1000 and deflector 1002. The opening angle a can be any suitable angle selected based on the desired incoming and/or outgoing velocities for the purge flow, desired directional specificity, or any other such suitable characteristics of the flow to be provided by diffuser 1000 and deflector 1002. Lines tangent to the deflector 1002 at deflector tip 1006 can form angles θ relative to a line tangent to the rearmost point of back surface 1008 of the deflector 1002. The angles θ can each be obtuse angles. The angles θ can define the nozzle, as discussed above for the acute opening angle a, and can be selected to provide suitable characteristics for the flow leaving deflector 1002 by way of the opening 1004.

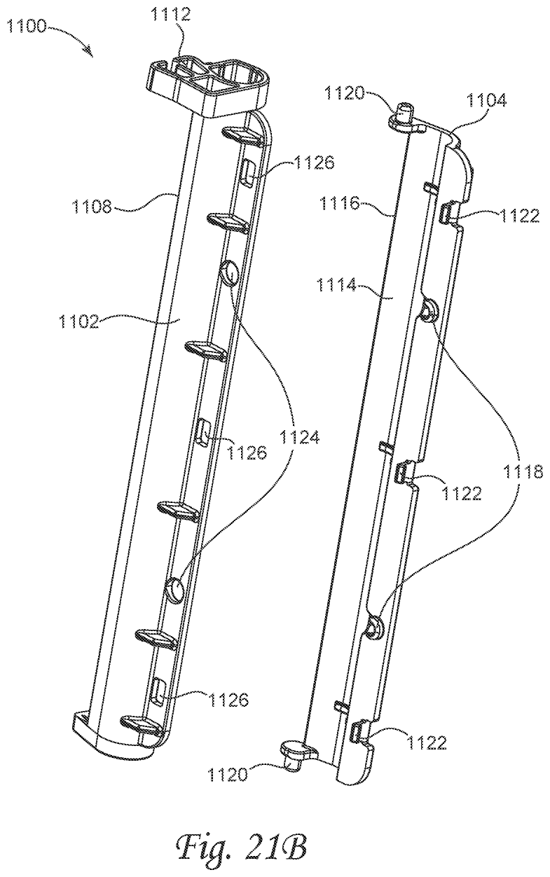

FIG. 21A shows an exploded perspective view of a deflector according to an embodiment. Deflector 1100 includes first piece 1102 and second piece 1104, which may be joined together, as described below. First piece 1102 includes first deflector surface 1106, first deflector edge 1108, diffuser engagement features 1110, and container engagement feature 1112. Second piece 1104 includes second deflector surface 1114, second deflector edge 1116, and drains 1118. Second piece 1104 further includes first attachment features 1120 and second attachment features 1122.

First piece 1102 and second piece 1104 are configured to be joined to one another, for example by way of a mechanical attachment, such as forming a snap-fit between the first piece 1102 and second piece 1104. In an embodiment, the snap-fit can be formed using features including first attachment features 1120, such as, for example, cylindrical projections provided on second piece 1104 engaging corresponding openings in first piece 1102, and second attachment features 1122 such as, for example, tabs including a snap-fit projection, engaging with attachment openings 1126 visible in FIG. 21B and discussed below. In an embodiment, first piece 1102 and second piece 1104 can be joined to one another following attachment of first piece 1102 to the diffuser by way of the diffuser engagement features 1110.

Diffuser engagement features 1110 are one or more features that may be sized, shaped, and positioned to allow first piece 1102 to be joined to a diffuser, such as any diffuser disclosed herein by way of mechanical engagement of the diffused by said diffuser engagement features 1110. In an embodiment, diffuser engagement features 1110 are configured such that the first piece 1102 can be slid over the diffuser, with the diffuser being inserted into in a channel defined by the diffuser engagement features 1110. The diffuser engagement features 1110 can partially surround and contact the diffuser such that the first piece 1102 is rotatably joined to the diffuser.

When first piece 1102 and second piece 1104 are joined together, first deflector surface 1106 and second deflector surface 1114 meet, forming a combined deflector surface configured to deflect and/or direct gas leaving the diffuser. The first deflector edge 1108 and second deflector edge 1116 define an opening of the deflector 1100. In an embodiment, the first deflector edge 1108 and second deflector edge 1116 are configured to define the opening such that the opening has an acute opening angle a as described above and shown in FIG. 20.

Container engagement feature 1112 is a feature configured to form a mechanical connection to a substrate container that the deflector 1100 is installed into so as to maintain a position of the deflector 1100 and the diffuser that the deflector 1100 is attached to. The connection formed by container engagement feature 1112 is a connection that can be selectively dis-engaged, for example a snap fit that can also be un-snapped without damage to the container or the container engagement feature 1112. The container engagement feature 1112 can be configured to engage with any suitable corresponding feature provided on the container, such as one or more substrate supports included in the container, a feature provided on or extending from a shell of the container, or the like.

Drains 1118 are provided on second piece 1104. The drains 1118 are configured to define an opening through deflector 1100 such that fluid can flow downwards into and through the drains 1118 when the diffuser is rotated such that the diffuser extends horizontally and deflector 1100 is oriented such that the drains 1118 are at a bottom of the deflector 1100. The drains 1118 can be positioned, sized, and shaped to control flow of gas from the diffuser through drains 1118, for example to reduce or minimize such flow of gas relative to the flow of gas through the opening defined by first and second deflector edges 1108, 1116. The position, size, and shape of the drains 1118 can be selected such that the pressure drops across the drains 1118 relative to the opening defined by first and second deflector edges 1108, 1116 are such that purge gas from the diffuser is significantly more likely to exit the deflector 1100 by way of said opening.

The drains 1118 can be used to allow water to drain out of deflector 1100 following cleaning of the diffuser and the deflector 1100. In such cleaning, container engagement feature 1112 can be detached from the body of the container such as the shell or the one or more substrate supports, and the diffuser rotated to a horizontal position, allowing water to run down to and out of the deflector 1100 by way of the drains 1118.

Outside of drains 1118, first piece 1102 and second piece 1104 meet can be in close proximity or contact with each other to reduce, minimize, or prevent gas provided by the diffuser from escaping the deflector 1100 through pathways other than the opening defined by first and second deflector edges 1108, 1116.

FIG. 21B shows another exploded perspective view of the deflector of FIG. 21A. In the exploded perspective view of deflector 1100 in FIG. 21B, first piece 1102 can be seen as including drain openings 1124 and attachment openings 1126. Drain openings 1124 are openings in first piece 1102 that the drains 1118 provided on second piece 1104 can at least partially extend through, such that the drains 1118 provide a path by which fluid can exit the deflector 1100 even when the first piece 1102 and second piece 1104 are joined together.

In the embodiments shown in FIGS. 21A and 21B, the drains 1118 are provided on the second piece 1104 and the drain openings 1124 are provided on the first piece; however, it is understood that at least some of the drains 1118 can instead be provided on the first piece 1102, and the corresponding drain openings 1124 can be provided on the second piece 1104.

The attachment openings 1126 are configured to engage with the second attachment features 1122 provided on the second piece 1104, such that a snap-fit can be formed to join the first piece 1102 and second piece 1104. In an embodiment, at least some of second attachment features 1122 can instead be provided on first piece 1102, with the corresponding attachment openings 1126 instead being provided on second piece 1104.

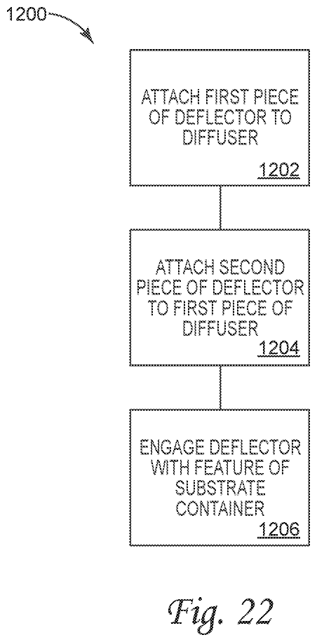

FIG. 22 shows a flowchart of a method for installing a deflector into a substrate container. Method 1200 includes attaching a first piece of the deflector to a diffuser 1202, attaching a second piece of the deflector to the first piece of the deflector 1204, and optionally engaging the deflector with a feature provided on the substrate container at 1206.

The first piece of the deflector, such as first piece 1102 discussed above and shown in FIGS. 21A and 21B, is attached to the diffuser at 1202. The attachment of the first piece of the deflector to the diffuser can include sliding the diffuser into one or more diffuser engagement features provided on the first piece of the deflector, for example inserting the diffuser into a channel defined by said engagement features. The diffuser engagement features can be, for example, the diffuser engagement features 1110 as discussed above and shown in FIGS. 21A and 21B.

The second piece of the deflector, such as second piece 1104 discussed above and shown in FIGS. 21A and 21B, is attached to the first piece of the deflector at 1204. The second piece can be joined to the first piece through any suitable mechanical connection or combinations thereof, for example one or more snap-fits between corresponding attachment features provided on the first and second pieces of the deflector such as, as non-limiting examples, the first and second attachment features 1120, 1122, and attachment openings 1126 as described above and shown in FIGS. 21A and 21B. When the second piece of the deflector is attached to the first piece of the deflector at 1204, the first and second deflectors can provide a deflector surface configured to deflect flow from the diffuser, for example according to the combination of the first deflector surface 1106 and second deflector surface 1114 as described above and shown in FIGS. 21A and 21B.

Optionally, the deflector can be attached to a feature of the substrate container at 1206. The deflector can include a container engagement feature, such as container engagement feature 1112 described above and shown in FIGS. 21A and 21B. The container engagement feature can engage a corresponding feature provided on the substrate container at 1206, and a connection such as, for example, a snap-fit formed between the container engagement feature and the corresponding feature of the substrate container. The corresponding feature can be any suitable feature provided on the container. In an embodiment, the corresponding feature of the substrate container can be an existing feature of the container, such as one or more of the substrate supports, a substrate tray, or other such structure. In an embodiment, the corresponding feature of the substrate container is a projection or other dedicated structure for interfacing with the container engagement feature. In an embodiment, the container engagement feature can positioned to engage the container by rotation of the diffuser from an installation position where one or both of 1202 and/or 1204 can be performed to an operation position where the container engagement feature and the corresponding feature of the substrate container are joined together.

Optionally, in an embodiment, the diffuser assembled and installed according to method 1200 can be rotated from the operation position to a cleaning position to allow the diffuser and deflector to be cleaned and to dry, for example by allowing cleaning fluids such as or including water to escape the deflector by way of drains provided on the deflector such as the drains 1118 described above and shown in FIGS. 21A and 21B.

Aspects:

Aspect 1. A system, comprising:
a deflector, disposed in an interior of a substrate container, having a longitudinal opening and a deflection surface; and
a gas distributor configured to provide a purging gas to purge the interior of the substrate container, wherein
   the gas distributor is configured such that at least a portion of the purging gas flows into a gap formed between the gas distributor and the deflector,
   the deflector is configured such that at least a portion of the purging gas in the gap flows through the longitudinal opening, and
   the deflector has an opening angle, wherein the opening angle is an acute angle.

Aspect 2. The system of aspect 1, wherein the deflector includes a first piece and a second piece, wherein the first piece and the second piece are configured to be joined to one another.

Aspect 3. The system of aspect 2, wherein the first piece is configured to engage with the gas distributor.

Aspect 4. The system of aspect 2, wherein the first piece is configured to engage with a feature provided on the substrate container.

Aspect 5. A system, comprising:
a substrate container having an interior configured to store substrates; and
a deflector, disposed in the interior of the substrate container, having a longitudinal opening; and
a gas distributor configured to provide a purging gas to purge the interior of the substrate container, wherein
   the gas distributor is configured such that at least a portion of the purging gas flows through the longitudinal opening into the interior of the substrate container,
   the deflector is configured such that the longitudinal opening directs the purging gas, and
   the deflector has an opening angle, wherein the opening angle is an acute angle.

Aspect 6. The system of aspect 5, wherein the deflector includes a first piece and a second piece, wherein the first piece and the second piece are configured to be joined to one another.

Aspect 7. The system of aspect 6, wherein the first piece is configured to engage with the gas distributor.

Aspect 8. The system of any one of aspects 6-7, wherein the first piece is configured to engage with a feature provided on the substrate container.

Aspect 9. The system of any of any one of aspects 5-8, further comprising:
an indexer configured to maintain a relative angular position between the gas distributor and the deflector or the deflection surface.

Aspect 10. The system of any one of aspects 5-9, further comprising one or more ribs extending from the deflection surface and is configured to engage with the gas distributor to maintain the relative angular position.

Aspect 11. The system of any one of aspects 5-10, wherein
the indexer comprises a spline joint having a first joint member and a second joint member,
the first joint member is disposed on the deflector, and
the second joint member is disposed on the substrate container.

Aspect 12. The system of any one of aspects 5-11, further comprising:
a stabilizer having a first end and a second end, wherein
   a first end of the stabilizer engages with the deflector, and
   a second end of the stabilizer engages with the substrate container to stabilize the deflector and the gas distributor.

Aspect 13. The system of any one of aspects 5-12, wherein the stabilizer is disposed with the indexer, wherein further
the indexer is disposed to maintain a relative angular position between the gas distributor and the deflector or the deflection surface,
the indexer comprises a spline joint having a first joint member and a second joint member,
the first joint member is disposed on the second end of the stabilizer, and
the second joint member is disposed on the substrate container.

Aspect 14. The system of any one of aspects 9-13, wherein the indexer extends through the substrate container such that:
a force turning the indexer from an exterior of the substrate container changes the relative angular position from a first angle to a second angle, and
the indexer maintains the relative angular position at the second angle when the force is removed.

Aspect 15. A method, comprising:
directing purging gas from a gas distributor disposed in a substrate container to a longitudinal opening in a deflector,
directing at least a portion of the purging gas, and
deflecting the purging gas in the interior of the substrate container to direct a gas flow pattern of the purging gas, wherein the gas flow pattern is from the gas distributor to an outlet of the substrate container to improve purging efficacy.

Aspect 16. The method of aspect 15, wherein directing the purging gas from the gas distributor to the longitudinal opening comprises:

directing at least a portion of the purging gas from the gas distributor to a gap formed between the deflector and the gas distributor.

Aspect 17. A system, comprising:
a substrate container having an interior disposed to store substrates;
a deflector, disposed in the interior of the substrate container, having a longitudinal opening and a deflection surface; and
one or more gas distributors configured to provide a purging gas to purge the interior of the substrate container, wherein
   the deflector is disposed over one of the one or more gas distributors,
   the longitudinal opening is disposed to direct the purging gas,
   the deflector is disposed to direct a gas flow pattern of the purging gas from the gas distributor to an outlet of the substrate container to improve purging efficacy of the substrate container, and
   the substrate container includes a centerline, a shoulder volume, and a lip volume.

Aspect 18. The system of aspect 17, wherein the one or more gas distributors is disposed in the shoulder volume of the substrate container.

Aspect 19. The system of at least one of aspect 17 or aspect 18, wherein the one or more gas distributors is disposed in the lip volume of the substrate container.

Aspect 20. The system of any one of aspects 17-19, wherein
a first gas distributor and a second gas distributor of the one or more gas distributors are disposed in the shoulder volume of the substrate container, and
a third gas distributor and a fourth gas distributor of the one or more gas distributors are disposed in the lip volume of the substrate container.

Aspect 21. The system of any one of aspects 17-20, wherein
the first gas distributor is opposite to the second gas distributor relative to the centerline, and
the third gas distributor is opposite to the fourth gas distributor relative to the centerline.

Aspect 22. The system of any one of aspects 17-21, wherein an angle between the centerline and a flow direction of the purging from the longitudinal opening is between 0° to 80°.

Aspect 23. The system of any one of aspects 17-22, wherein the angle is 15° to 25°.

Aspect 24. The system of any one of aspects 17-23, wherein at least one other of the one or more gas distributors is disposed across the lip volume.

Aspect 25. The system of aspects any one of aspects 17-24, further comprising:
an empty deflector disposed at the lip volume of the substrate container, and
the empty deflector includes an elongated body to direct the gas flow pattern of the purging gas from the gas distributor to an outlet of the substrate container to improve purging efficacy.

Aspect 26. The system of any one of aspects 1, 3-14, and 17-25, wherein the longitudinal opening is disposed to direct the purging gas toward a central volume of the interior of the substrate container.

Aspect 27. The system of any one of aspects 1, 3-14, and 17-25, wherein the longitudinal opening is disposed to direct the purging gas away from a central volume of the interior of the substrate container.

Aspect 28. The system of any one of aspects 1, 3-14, and 17-25, wherein the longitudinal opening is disposed to direct the purging gas toward a back of the substrate container.

Aspect 29. The method of aspect 15 or 16, wherein directing at least a portion of the purging gas includes directing the portion of the purging gas toward a central volume of the interior of the substrate container.

Aspect 30. The method of aspect 15 or 16, wherein directing at least a portion of the purging gas includes directing the portion of the purging gas direct the purging gas away from a central volume of the interior of the substrate container.

Aspect 31. The method of aspect 15 or 16, wherein directing at least a portion of the purging gas includes directing the portion of the purging gas direct the purging gas toward a back of the substrate container.

What is claimed is:

1. A system, comprising:
a deflector, disposed in an interior of a substrate container, having a longitudinal opening and a deflection surface; and
a gas distributor configured to provide a purging gas to purge the interior of the substrate container, wherein
the gas distributor is configured such that at least a portion of the purging gas flows into a gap formed between the gas distributor and the deflector,
the deflector is configured such that at least a portion of the purging gas in the gap flows through the longitudinal opening of the deflector, and
the deflector has an acute opening angle.

2. The system of claim 1, wherein the deflector includes a first piece and a second piece, wherein the first piece and the second piece are configured to be joined to one another.

3. The system of claim 2, wherein the first piece is configured to engage with the gas distributor.

4. The system of claim 2, wherein the first piece is configured to engage with a feature provided on the substrate container.

5. The system of claim 1, wherein
the gas distributor is an elongated member, and
the deflection surface is spaced apart radially from the gas distributor.

6. The system of claim 1, wherein the gap between the gas distributor and the deflection surface is between 0.5 to 3 millimeters.

7. A system, comprising:
a substrate container having an interior disposed to store substrates; and
a deflector, disposed in the interior of the substrate container, having a longitudinal opening and a deflection surface; and
a gas distributor disposed to provide a purging gas to purge the interior of the substrate container, wherein
the gas distributor is configured such that at least a portion of the purging gas flows through the longitudinal opening into the interior of the substrate container,
the deflector is configured such that the longitudinal opening is disposed to direct the purging gas, and
the deflector has an acute opening angle.

8. The system of claim 7, wherein the deflector includes a first piece and a second piece, wherein the first piece and the second piece are configured to be joined to one another.

9. The system of claim 8, wherein the first piece is configured to engage with the gas distributor.

10. The system of claim 8, wherein the first piece is configured to engage with a feature provided on the substrate container.

11. The system of claim 7, further comprising:
an indexer disposed to maintain a relative angular position between the gas distributor and the deflector or the deflection surface.

12. The system of claim 11, further comprising one or more ribs extending from the deflection surface and disposed to engage with the gas distributor to maintain the relative angular position.

13. The system of claim 11, wherein
the indexer comprises a spline joint having a first joint member and a second joint member,
the first joint member is disposed on the deflector, and
the second joint member is disposed on the substrate container.

14. The system of claim 7, further comprising:
a stabilizer having a first end and a second end, wherein
a first end of the stabilizer engages with the deflector, and
a second end of the stabilizer engages with the substrate container to stabilize the deflector and the gas distributor.

15. The system of claim 14, wherein the stabilizer is disposed with an indexer, wherein further
the indexer is disposed to maintain a relative angular position between the gas distributor and the deflector or the deflection surface,
the indexer comprises a spline joint having a first joint member and a second joint member,
the first joint member is disposed on the second end of the stabilizer, and
the second joint member is disposed on the substrate container.

16. The system of claim 11, wherein the indexer extends through the substrate container such that:
a force turning the indexer from an exterior of the substrate container changes the relative angular position from a first angle to a second angle, and
the indexer maintains the relative angular position at the second angle when the force is removed.

17. The system of claim 7, wherein the longitudinal opening is disposed to direct the purging gas toward a central volume of the interior of the substrate container.

18. The system of claim 7, wherein the longitudinal opening is disposed to direct the purging gas away from a central volume of the interior of the substrate container.

19. The system of claim 7, wherein the longitudinal opening is disposed to direct the purging gas toward a back of the substrate container.
